(19) United States
(12) Patent Application Publication
(10) Pub. No.: US 2025/0054801 A1
(43) Pub. Date: Feb. 13, 2025

(54) METHOD OF FABRICATING DISPLAY PANEL

(71) Applicant: Samsung Display Co., LTD., Yongin-si (KR)

(72) Inventor: Jong Hyup KIM, Yongin-si (KR)

(21) Appl. No.: 18/790,210

(22) Filed: Jul. 31, 2024

(30) Foreign Application Priority Data
Aug. 7, 2023 (KR) 10-2023-0102949

(51) Int. Cl. H01L 21/683; H01L 27/15

(52) U.S. Cl. CPC H01L 21/6835; H01L 27/156; H01L 2221/68354; H01L 2221/68368; H01L 2221/68381

(57) ABSTRACT

A method of fabricating a display panel includes forming light-emitting elements on a base substrate, initially transferring the light-emitting elements to a first film, securing the first film on which the light-emitting elements are arranged, elongating the first film by pressurizing the first film with gas, and secondarily transferring the light-emitting elements, which are rearranged by elongating the first film, to a second film secured to a stage.

### CROSS-REFERENCE TO RELATED APPLICATION

The present application claims priority to, and the benefit of, Korean Patent Application No. 10-2023-0102949, filed Aug. 7, 2023, in the Korean Intellectual Property Office, the entire disclosure of which is incorporated herein by reference.

### BACKGROUND

### 1. Field

One or more embodiments described herein relate to a method of fabricating a display panel.

### 2. Description of Related Art

With the development of information technology, the importance of a display device, which is a connection medium between a user and information, has been emphasized. Owing to the importance of display devices, the use of various kinds of display devices, such as a liquid crystal display device and an organic light-emitting display device, has increased.

Display panels, such as an emission display panel or a liquid crystal display panel, may be used as devices for displaying images on the display devices. Among the aforementioned examples, the emission display panel may include a plurality of light-emitting elements. For example, the light-emitting elements may include organic light-emitting elements that use organic material as fluorescent material, or inorganic light-emitting elements that use inorganic material as fluorescent material.

In the fabrication of display panels that use the inorganic light-emitting elements as the light-emitting elements, there is a need to precisely arrange micro LEDs on a substrate of a display panel.

### SUMMARY

Various embodiments of the present disclosure are directed to a method of fabricating a display panel on which a plurality of light-emitting elements are substantially uniformly and precisely arranged.

One or more embodiments of the present disclosure may provide a method of fabricating a display panel, the method including forming light-emitting elements on a base substrate, initially transferring the light-emitting elements to a first film, securing the first film on which the light-emitting elements are arranged, elongating the first film by pressurizing the first film with gas, and secondarily transferring the light-emitting elements, which are rearranged by elongating the first film, to a second film secured to a stage.

Elongating the first film way include elongating the first film in a spherical shape.

The gas may include air.

A distance between the light-emitting elements may increase due to elongating the first film.

Elongating the first film may include elongating the first film to the second film spaced apart from the first film.

Secondarily transferring the light-emitting elements may include pressurizing, with the gas, a portion of the first film on which the light-emitting elements are positioned, such that the portion is parallel to the second film.

The method may further include locating the second film on a cell mask that is above a display substrate and that defines cell openings, pressurizing a portion of the second film with the gas, and irradiating the portion of the second film with a laser.

The portion of the second film may overlap one of cell openings.

In pressurizing the portion of the second film, the light-emitting elements rearranged and positioned in the portion of the second film may contact the display substrate.

In irradiating the portion, the light-emitting elements rearranged and positioned in the portion of the second film may be bonded to the display substrate.

Pressurizing the portion of the second film and irradiating the portion may be performed on a basis of the cell openings.

In secondarily transferring the light-emitting elements, the stage may move downwardly toward the first film.

In secondarily transferring the light-emitting elements, the stage may move downwardly toward the first film while being inclined.

In secondarily transferring the light-emitting elements, the first film may move upwardly toward the second film.

In secondarily transferring the light-emitting elements, the first film may move upwardly toward the second film while being inclined.

### BRIEF DESCRIPTION OF DRAWINGS

FIG. 1 is a plan view of a display device in accordance with one or more embodiments of the present disclosure.

FIG. 2 is a plan view schematically illustrating an emission area of each pixel in accordance with one or more embodiments.

FIG. 3 is a plan view schematically illustrating an emission area of each pixel in accordance with one or more embodiments.

FIG. 4 is an equivalent circuit diagram of each pixel in accordance with one or more embodiments.

FIG. 5 is an equivalent circuit diagram of each pixel in accordance with one or more embodiments.

FIG. 6 is a sectional view schematically illustrating a cross-section taken along the line A-A′ of FIG. 2 in accordance with one or more embodiments.

FIG. 7 is an enlarged view schematically illustrating a first emission area of FIG. 6.

FIG. 8 is a sectional view illustrating in detail the light-emitting element of FIG. 7.

FIG. 9 is a sectional view schematically illustrating a cross-section taken along the line A-A′ of FIG. 2 in accordance with one or more embodiments.

FIG. 10 is a sectional view schematically illustrating a cross-section taken along the line A-A′ of FIG. 2 in accordance with one or more embodiments.

FIG. 11 is a flowchart for describing a method of fabricating a display panel in accordance with one or more embodiments.

FIGS. 12 to 30 are diagrams schematically illustrating a process of fabricating the display panel in accordance with one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components such as “between,” “immediately between” or “adjacent to” and “directly adjacent to” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression such as “at least one of A and B” and “at least one of A or B” may include A, B, or A and B. As used herein, “or” generally means “and/or,” and the term “and/or” includes any and all combinations of one or more of the associated listed items. For example, the expression such as “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

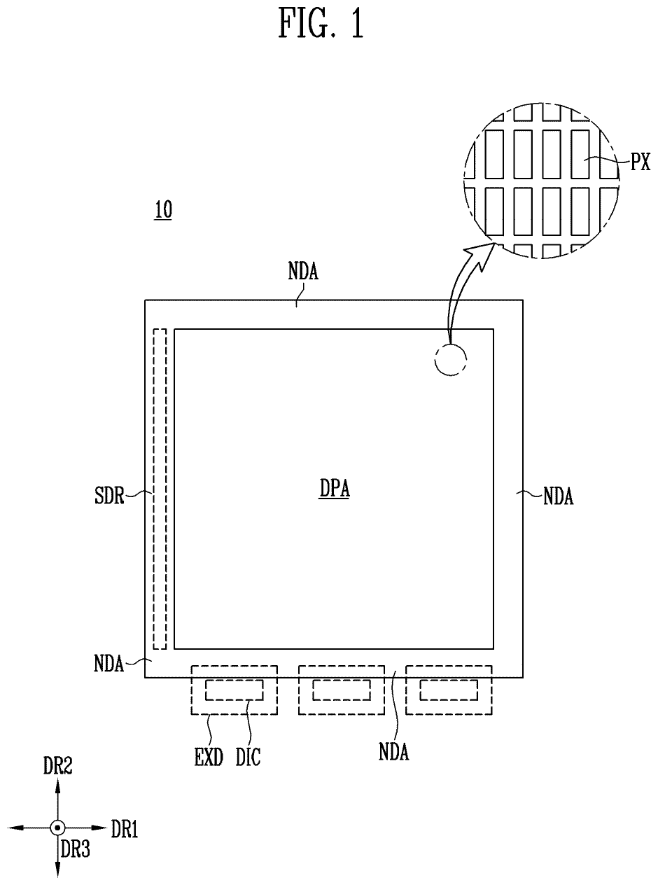

FIG. 1 is a plan view of a display device 10 in accordance with one or more embodiments of the present disclosure.

Referring to FIG. 1, the display device 10 may be applied to a smartphone, a mobile phone, a tablet PC, a personal digital assistant (PDA), a portable multimedia player (PMP), a television, a gaming console, a wristwatch-style electronic device, a head-mounted display, a monitor for personal computers, a laptop computer, a car navigation system, an automotive dashboard, a digital camera, a camcorder, an outdoor billboard, an electronic scoreboard, a medical device, an inspection device, home appliances, such as a refrigerator and a washing machine, or an Internet of Thing (IoT) device.

The display device 10 may be classified into various categories based on the display scheme. For example, the display device 10 may be classified into an organic light-emitting diode (OLED) display device, an inorganic light-emitting (inorganic EL) display device, a quantum dot light-emitting diode (QED) display device, a micro LED (micro-LED) display device, a nano LED display device, a plasma display panel (PDP), a field emission display (FED) device, a cathode ray tube (CRT) display device, a liquid crystal display (LCD) device, an electrophoretic display (EPD) device, or the like. Hereinafter, a micro LED display device will be described as an example of the display device 10, and unless specifically mentioned otherwise, the micro-LED display device applied in the embodiments will be simply referred to as the display device 10. However, the embodiments are not limited to the micro-LED display device, and other display devices listed above or known in the art within the scope of the technical concept may also be applied.

Furthermore, in the following drawings, a first direction DR1 refers to a horizontal direction of the display device 10, a second direction DR2 refers to a vertical direction of the display device 10, and a third direction DR3 refers to a thickness direction of the display device 10. In this case, “left,” “right,” “up,” and “down” indicate the directions in a plan view of the display device 10. For example, “right side” indicates one side of the first direction DR1, “left side” indicates the other side of the first direction DR1, “upper side” may indicate one side of the second direction DR2, and “lower side” may indicate the other side of the second direction DR2. In addition, “upper portion” may indicate one side of the third direction DR3, and “lower portion” may indicate the other side of the third direction DR3.

In a plan view, the display device 10 may have a circular shape, an elliptical shape, or a quadrate shape and, for example, have a square shape. Furthermore, in a case where the display device 10 is a television, the display device 10 may have a rectangular shape in which long sides are aligned in the horizontal direction. However, the present disclosure is not limited thereto, and the long sides may be aligned in the vertical direction, or the display device 1 may be rotatably installed so that the long sides can be variably aligned in either the horizontal or vertical direction.

The display device 10 may include a display area DPA and a non-display area NDA. The display area DPA may be an active area in which an image is displayed. The display area DPA may have a square shape in a plan view in a manner similar to the overall shape of the display device 10, but is not limited thereto. For example, the display area DPA may have a circular shape or an elliptical shape.

The display area DPA may include a plurality of pixels PX. The plurality of pixels PX may be arranged in a matrix direction. The shape of each pixel PX has a rectangular shape or a square shape in a plan view, but is not limited thereto, and may have a rhombus shape in which each side is inclined with respect to one side direction of the display device 10. The plurality of pixels PX may include various colors of pixels PX. For example, the plurality of pixels PX may include, without limitation, a first-color pixel PX in red, a second-color pixel PX in green, and a third-color pixel PX in blue. Respective color pixels PX may be alternately arranged in a stripe type or a PENTILE™ type configuration (PENTILE™ being a registered trademark of Samsung Display Co., Ltd., Republic of Korea).

The non-display area NDA may be located around the display area DPA. The non-display area NDA may enclose the entirety or a portion of the display area DPA. The display area DPA may have various shapes, such as a circular shape and a square shape. The non-display area NDA may be formed in a shape enclosing the periphery of the display area DPA. The non-display area NDA may be configured as a bezel of the display device 10.

A driving circuit or a driving element configured to drive the display area DPA may be located in the non-display area NDA. In one or more embodiments, in the non-display area NDA located adjacent to a first side of the display device 10 (or a lower side in FIG. 1), a pad component may be provided on a display substrate of the display device 10, and an external device EXD may be mounted on a pad electrode of the pad component. Examples of the external device EXD may include a connection film, a printed circuit board, a driving chip DIC, a connector, a line connection film, and so on. In the non-display area NDA adjacent to a second side of the display device 10 (or a left side in FIG. 1), a scan-driving component SDR formed directly on the display substrate of the display device 10 may be located.

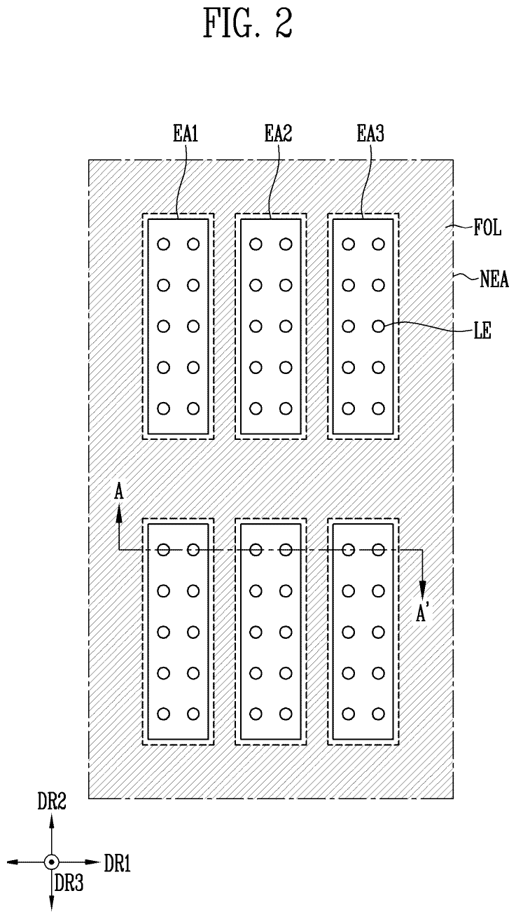

FIG. 2 is a plan view schematically illustrating an emission area of each pixel in accordance with one or more embodiments.

Referring to FIG. 2, a plurality of pixels PX may be arranged in a matrix direction. The plurality of pixels PX may be divided into a first-color pixel PX in red, a second-color pixel PX in green, and a third-color pixel PX in blue. Furthermore, a fourth-color pixel PX in white may be further included.

A pixel electrode of the first-color pixel PX may be positioned in a first emission area EA1, and at least a portion thereof may extend to a non-emission area NEA. A pixel electrode of the second-color pixel PX may be positioned in a second emission area EA2, and at least a portion thereof may extend to the non-emission area NEA. A pixel electrode of the third-color pixel PX may be positioned in a third emission area EA3, and at least a portion thereof may extend to the non-emission area NEA. The pixel electrode of each of the pixels PX may be connected to any one switching element included in the corresponding pixel circuit through at least one insulating layer.

A plurality of light-emitting elements LE are located on the pixel electrode of the first emission area EA1, the pixel electrode of the second emission area EA2, and the pixel electrode of the third emission area EA3. In other words, the light-emitting elements LE are located in each of the first emission area EA1, the second emission area EA2, and the third emission area EA3. A first color filter in red, a second color filter in green, and a third color filter in blue may be respectively located on the first emission area EA1, the second emission area EA2, and the third emission area EA3 in which the plurality of light-emitting elements LE are located. A first organic layer FOL may be located in the non-emission area NEA.

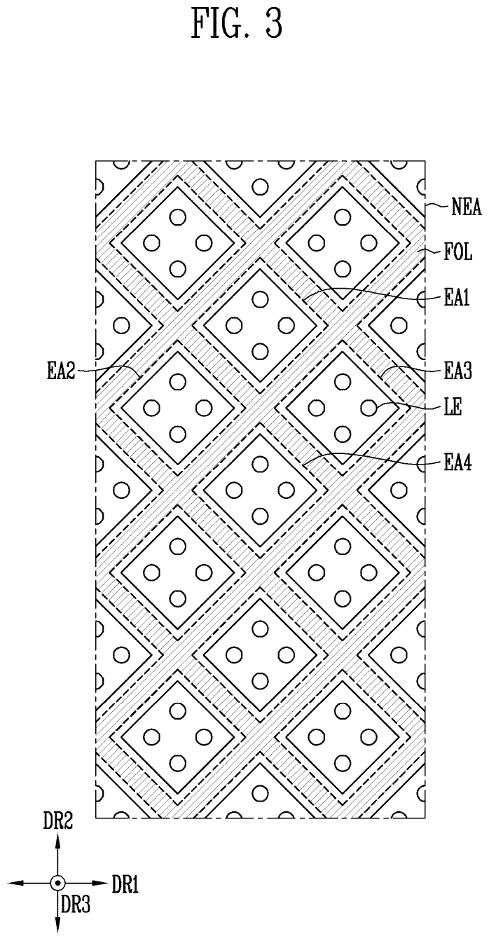

FIG. 3 is a plan view schematically illustrating an emission area of each pixel in accordance with one or more embodiments.

Referring to FIG. 3, the shape of each of the pixels PX is not limited to a rectangular or square shape, in a plan view, and may have a rhombus shape, each side of which is inclined with respect to one side direction of the display device 10, thus forming a PENTILE™ structure. In each of the pixels PX having a PENTILE™ structure, a first emission area EA1 of a first-color pixel PX, a second emission area EA2 of a second-color pixel PX, a third emission area EA3 of a third-color pixel PX, and a fourth emission area EA4 of a color pixel PX in any one color among the first to third colors, may each have a rhombus shape.

The size or planar surface area of each of the first to fourth emission areas EA1 to EA4 of each pixel PX may be the same or vary. Likewise, the number of light-emitting elements LE formed in the first to fourth emission areas EA1 to EA4 may be the same or vary.

The surface area of the first emission area EA1, the surface area of the second emission area EA2, the surface area of the third emission area EA3, and the surface of the fourth emission area EA4 may be the same or similar, but are not limited thereto, and may be different from each other. A distance between the first emission area EA1 and the second emission area EA2 adjacent to each other, a distance between the second emission area EA2 and the third emission area EA3 adjacent to each other, a distance between the first emission area EA1 and the third emission area EA3 adjacent to each other, and a distance between the third emission area EA3 and the fourth emission area EA4 adjacent to each other may be the same or similar as each other, or may be different from each other. Embodiments of the present disclosure are not limited to the aforementioned example.

Furthermore, the first emission area EA1 may emit first light, the second emission area EA2 may emit second light, and the third emission area EA3 and the fourth emission area EA4 may emit third light, but the embodiments of the present disclosure are not limited thereto. For example, the first emission area EA1 may emit the second light, the second emission area EA2 may emit the first light, and the third emission area EA3 and the fourth emission area EA4 may emit the third light. Alternatively, the first emission area EA1 may emit the third light, the second emission area EA2 may emit the second light, and the third emission area EA3 and the fourth emission area EA4 may emit the first light. As a further alternative, at least one emission area among the first to fourth emission areas EA1 to EA4 may emit fourth light. The fourth light may be light in a yellow wavelength band. In other words, a main peak wavelength of the fourth light may be positioned within a range from about 550 nm to about 600 nm, but the embodiments of the present embodiments are not limited thereto.

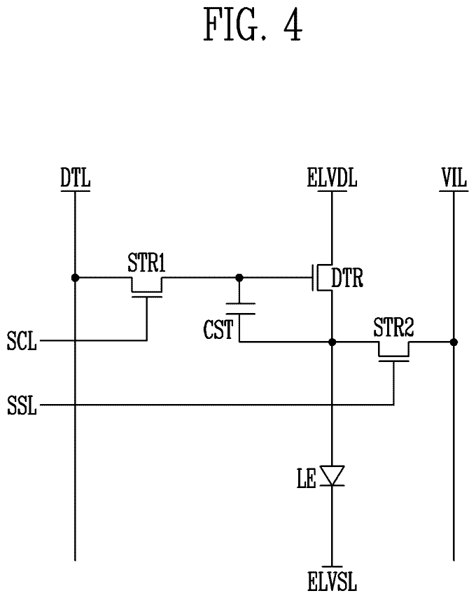

FIG. 4 is an equivalent circuit diagram of each pixel in accordance with one or more embodiments.

Referring to FIG. 4, each pixel PX may include three transistors DTR, STR1, and STR2, and one storage capacitor CST to drive light-emitting elements LE. The driving transistor DTR may adjust current flowing from a first power line ELVDL, to which a first power voltage is supplied, to any one light-emitting element LE in response to a difference in voltage between a gate electrode and a source electrode. The gate electrode of the driving transistor DTR may be connected to a first electrode of the first transistor STR1. The source electrode of the driving transistor DTR may be connected to a first electrode of any one light-emitting element LE. The drain electrode of the driving transistor DTR may be connected to the first power line ELVDL to which the first power voltage is applied.

The first transistor STR1 may be turned on by a scan signal from a scan line SCL, thus connecting a data line DTL to the gate electrode of the driving transistor DTR. A gate electrode of the first transistor STR1 may be connected to the scan line SCL. The first electrode of the first transistor STR1 may be connected to the gate electrode of the driving transistor DTR. A second electrode of the first transistor STR1 may be connected to the data line DTL.

The second transistor STR2 may be turned on by a sensing signal from a sensing signal line SSL, thus connecting an initialization voltage line VIL to the source electrode of the driving transistor DTR. A gate electrode of the second transistor STR2 may be connected to the sensing signal line SSL. A first electrode of the second transistor STR2 may be connected to the initialization voltage line VIL. A second electrode of the second transistor STR2 may be connected to the source electrode of the driving transistor DTR.

In one or more embodiments, the first electrode of each of the first and second transistors STR1 and STR2 may be a source electrode, and the second electrode thereof may be a drain electrode, but the present disclosure is not limited thereto, and the opposite configuration is also possible.

The storage capacitor CST may be formed between the gate electrode and the source electrode of the driving transistor DTR. The storage capacitor CST may store a voltage corresponding to a difference in voltage between the gate electrode and the source electrode of the driving transistor DTR.

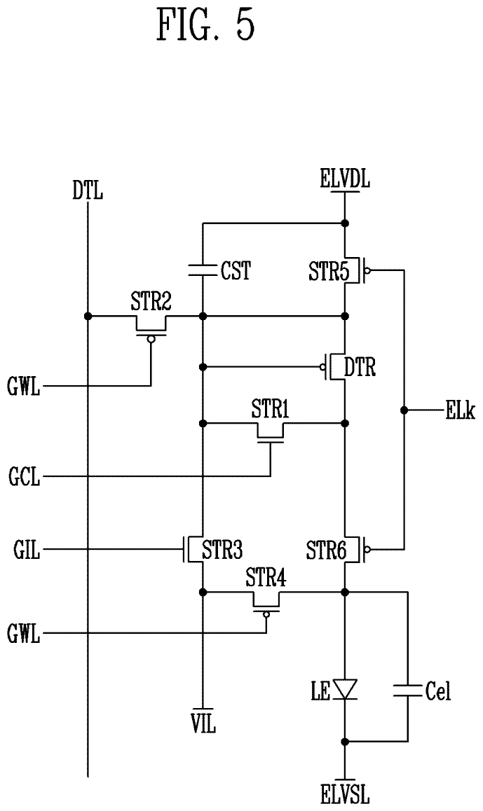

The driving transistor DTR and the first and second transistors STR1 and STR2 may each be formed of a thin-film transistor. Furthermore, although in FIG. 5 there has been described that the driving transistor DTR and the first and second switching transistors STR1 and STR2 each are formed of an N-type metal oxide semiconductor field effect transistor (MOSFET), the present disclosure is not limited thereto. In other words, the driving transistor DTR and the first and second switching transistors STR1 and STR2 may each be formed of a P-type MOSFET, or one or more may be formed of an N-type MOSFET, and one or more others may be formed of a P-type MOSFET.

FIG. 5 is an equivalent circuit diagram of each pixel in accordance with one or more embodiments.

Referring to FIG. 5, each pixel PX may include a transistor DTR, switch elements, and a storage capacitor CST to emit light-emitting elements LE. The switch elements may include first to sixth transistors STR1, STR2, STR3, STR4, STR5, and STR6.

The driving transistor DTR may include a gate electrode, a first electrode, and a second electrode. The driving transistor DTR may control drain-source current (hereinafter, referred to as “driving current”) flowing between the first electrode and the second electrode in response to a data voltage applied to the gate electrode.

The capacitor CST may be formed between the second electrode of the driving transistor DTR and a second power line ELVSL. One electrode of the capacitor CST may be connected to the second electrode of the driving transistor DTR, and the other electrode thereof may be connected to the second power line ELVSL.

In the case where the first electrode of each of the first to sixth transistors STR1, STR2, STR3, STR4, STR5, and STR6 and the driving transistor DTR is a source electrode, the second electrode thereof may be a drain electrode. Alternatively, in the case where the first electrode of each of the first to sixth transistors STR1, STR2, STR3, STR4, STR5, and STR6 and the driving transistor DTR is a drain electrode, the second electrode thereof may be a source electrode.

The driving transistor DTR, the second transistor STR2, the fourth transistor STR4, the fifth transistor STR5, and the sixth transistor STR6 may each be formed of a P-type MOSFET, and the first transistor STR1 and the third transistor STR3 may each be formed of an N-type MOSFET. Alternatively, the first to sixth transistors STR1, STR2, STR3, STR4, STR5, and STR6 and the driving transistor DTR may each be formed of a P-type MOSFET.

It should be noted that the equivalent circuit diagram of the pixel PX in accordance with the aforementioned embodiments of this specification is not limited to that shown in FIGS. 4 and 5. The equivalent circuit diagram of the pixel PX in accordance with the embodiments of this specification may be formed in other circuit structures that are well-known and employed by those skilled in the art, in addition to the embodiments shown in FIGS. 4 and 5.

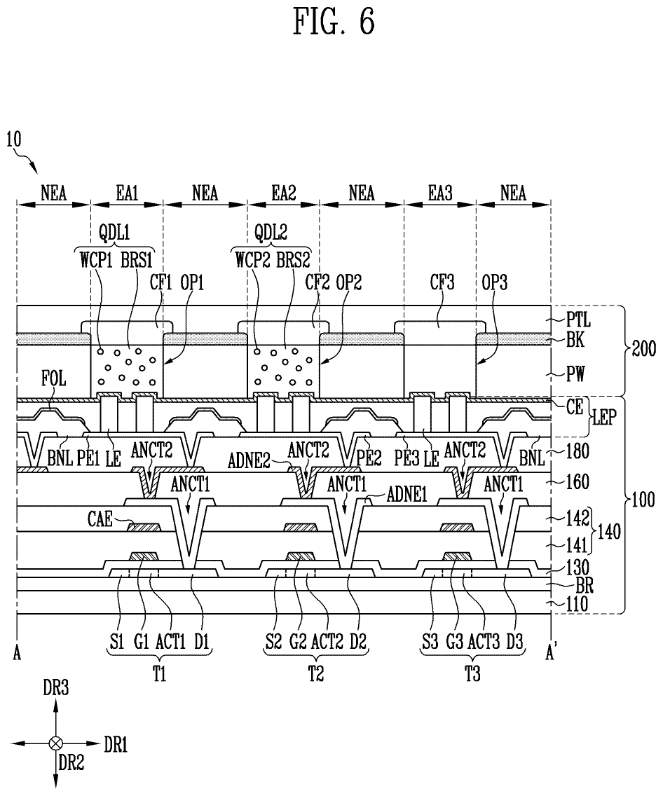

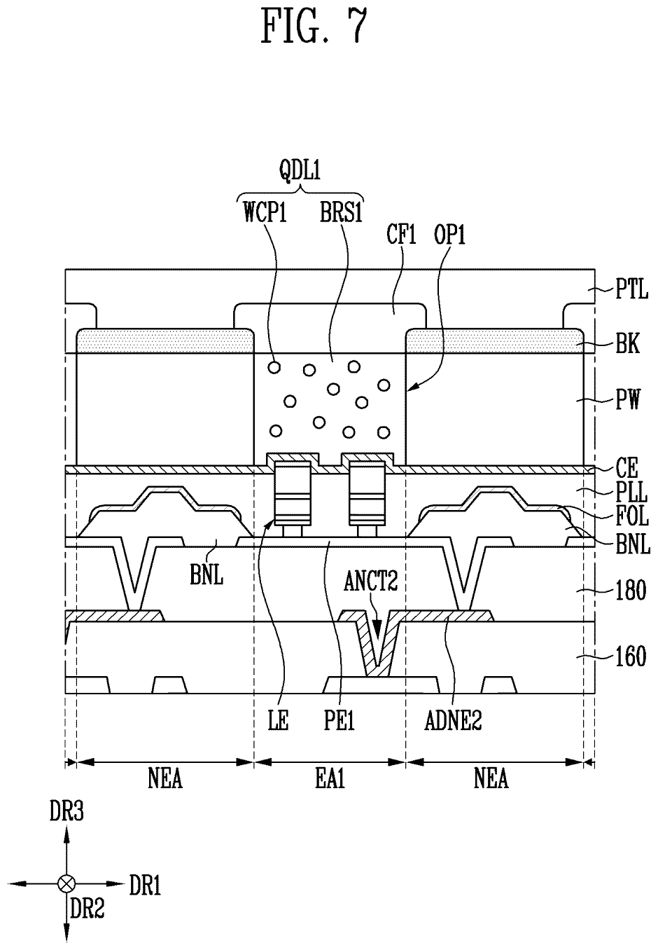

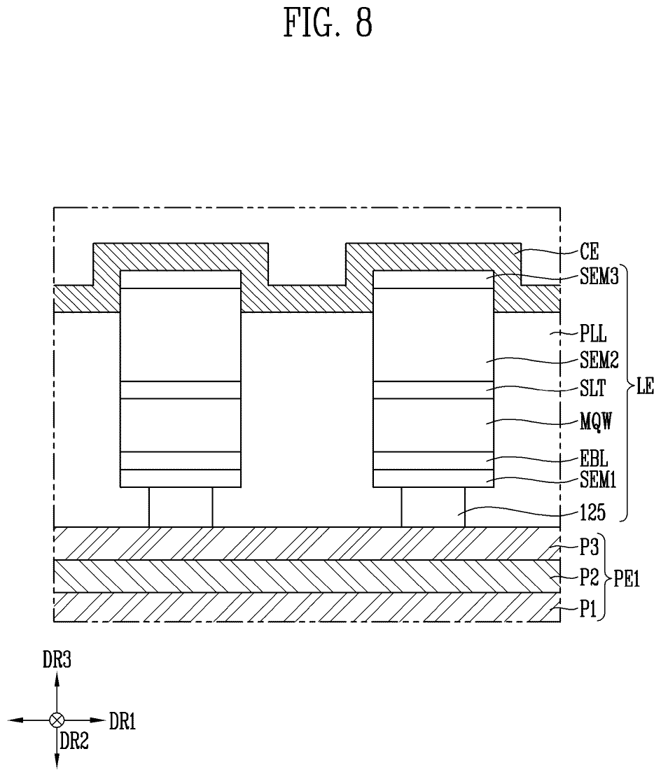

FIG. 6 is a sectional view schematically illustrating a cross-section taken along the line A-A′ of FIG. 2 in accordance with one or more embodiments. FIG. 7 is an enlarged view schematically illustrating a first emission area of FIG. 6. FIG. 8 is a sectional view illustrating in detail the light-emitting element of FIG. 7.

Referring to FIGS. 6 to 8, a display panel of the display device 10 may include a display substrate 100, and a wavelength conversion component 200 located on the display substrate 100.

A barrier layer BR may be located on a first substrate 110 of the display substrate 100. The first substrate 110 may be formed of insulating material, such as polymer resin. For example, the first substrate 110 may be formed of polyimide. The first substrate 110 may be a flexible substrate capable of bending, folding, rolling, or the like.

The barrier layer BR may be a layer provided to protect thin-film transistors T1, T2, and T3 and a light-emitting-element component LEP from moisture that may penetrate through the first substrate 110, which is vulnerable to moisture penetration. The barrier layer BR may be formed of a plurality of inorganic layers that are alternately stacked. For example, the barrier layer BR may be formed as a multilayer structure provided by alternately stacking one or more inorganic layers among a silicon nitride layer, a silicon oxynitride layer, a silicon oxide layer, a titanium oxide layer, and an aluminum oxide layer.

The transistors T1, T2, and T3 may be located on the barrier layer BR. Each of the thin-film transistors T1, T2, and T3 may include an active layer ACT1/ACT2/ACT3, a gate electrode G1/G2/G3, a source electrode S1/S2/S3, and a drain electrode D1/D2/D3.

The active layers ACT1/ACT2/ACT3, the source electrodes S1/S2/S3, and the drain electrodes D1/D2/D3 of the thin-film transistors T1, T2, and T3 may be located on the barrier layer BR. The active layer ACT1 of each of the thin-film transistors T1, T2, and T3 may include polycrystalline silicon, single-crystal silicon, low-temperature polycrystalline silicon, amorphous silicon, or an oxide semiconductor. The active layer ACT1/ACT2/ACT3 overlapping the gate electrode G1/G2/G3 in the third direction DR3, which is a thickness direction of the first substrate 110, may be defined as a channel area. Each of the source electrode S1/S2/S3 and the drain electrode D1/D2/D3 is an area that does not overlap the gate electrode G1/G2/G3 in the third direction DR3, and may have conductivity by doping a silicon semiconductor or an oxide semiconductor with ions or impurities.

A gate-insulating layer 130 may be located on the active layers ACT1/ACT2/ACT3, the source electrodes S1/S2/S3, and the drain electrodes D1/D2/D3 of the thin-film transistors T1, T2, and T3. The gate-insulating layer 130 may be formed of an inorganic layer, e.g., a silicon nitride layer, a silicon oxynitride layer, a silicon oxide layer, a titanium oxide layer, or an aluminum oxide layer.

The gate electrodes G1/G2/G3 of the thin-film transistors T1, T2, and T3 may be located on the gate-insulating layer 130. The gate electrode G1 may overlap the active layer ACT1 in the third direction (Z-axis direction). The gate electrode G1 may have a single layer or multilayer structure formed of any one of molybdenum (Mo), aluminum (Al), chromium (Cr), gold (Au), titanium (Ti), nickel (Ni), neodymium (Nd), copper (Cu), or an alloy thereof.

A first interlayer insulating layer 141 may be located on the gate electrodes G1/G2/G3 of the thin-film transistors T1, T2, and T3. The first interlayer insulating layer 141 may be formed of an inorganic layer, e.g., a silicon nitride layer, a silicon oxynitride layer, a silicon oxide layer, a titanium oxide layer, or an aluminum oxide layer. The first interlayer insulating layer 141 may be formed of a plurality of inorganic layers.

A capacitor electrode CAE may be located on the first interlayer insulating layer 141. The capacitor electrode CAE may overlap the gate electrodes G1/G2/G3 of the thin-film transistors T1, T2, and T3 in the third direction DR3. Because the first interlayer insulating layer 141 has a certain dielectric constant, a capacitor may be formed by the capacitor electrode CAE, the gate electrode G1, and the first interlayer insulating layer 141 therebetween. The capacitor electrode CAE may have a single layer or multilayer structure formed of any one of molybdenum (Mo), aluminum (Al), chromium (Cr), gold (Au), titanium (Ti), nickel (Ni), neodymium (Nd), copper (Cu), or an alloy thereof.

A second interlayer insulating layer 142 may be located on the capacitor electrode CAE. The second interlayer insulating layer 142 may be formed of an inorganic layer, e.g., a silicon nitride layer, a silicon oxynitride layer, a silicon oxide layer, a titanium oxide layer, or an aluminum oxide layer. The second interlayer insulating layer 142 may be formed of a plurality of inorganic layers.

A first anode connection electrode ADNE1 may be located on the second interlayer insulating layer 142. The first anode connection electrode ADNE1 may be connected to the drain electrode D1 of the thin-film transistor T1 through a first connection contact hole ANCT1 passing through the gate-insulating layer 130, the first interlayer insulating layer 141, and the second interlayer insulating layer 142. The first anode connection electrode ADNE1 may have a single layer or multilayer structure formed of any one of molybdenum (Mo), aluminum (Al), chromium (Cr), gold (Au), titanium (Ti), nickel (Ni), neodymium (Nd), copper (Cu), or an alloy thereof.

A first planarization layer 160 may be located on the first anode connection electrode ADNE1 to planarize a stepped portion formed due to the thin-film transistors T1, T2, and T3. The first planarization layer 160 may be formed of an organic layer made of, for example, acryl resin, epoxy resin, phenolic resin, polyamide resin, polyimide resin, or the like.

A second anode connection electrode ADNE2 may be located on the first planarization layer 160. The second anode connection electrode ADNE2 may be connected to the first anode connection electrode ADNE1 through a second connection contact hole ANCT2 passing through the first planarization layer 160. The second anode connection electrode ADNE2 may have a single layer or multilayer structure formed of any one of molybdenum (Mo), aluminum (Al), chromium (Cr), gold (Au), titanium (Ti), nickel (Ni), neodymium (Nd), copper (Cu), or an alloy thereof.

A second planarization layer 180 may be located on the second anode connection electrode ADNE2. The second planarization layer 180 may be formed of an organic layer made of, for example, acryl resin, epoxy resin, phenolic resin, polyamide resin, polyimide resin, or the like.

The light-emitting-element component LEP may be formed on the second planarization layer 180. The light-emitting-element component LEP may include a plurality of pixel electrodes PE1, PE2, and PE3, a plurality of light-emitting elements LE, and a common electrode CE.

The plurality of pixel electrodes may include a first pixel electrode PE1, a second pixel electrode PE2, and a third pixel electrode PE3. The first pixel electrode PE1, the second pixel electrode PE2, and the third pixel electrode PE3 may function as the first electrode of the light-emitting element LE, and may be an anode electrode or a cathode electrode. The first pixel electrode PE1 may be positioned in the first emission area EA1, and at least a portion thereof may extend to the non-emission area NEA. The second pixel electrode PE2 may be positioned in the second emission area EA2, and at least a portion thereof may extend to the non-emission area NEA. The third pixel electrode PE3 may be positioned in the third emission area EA3, and at least a portion thereof may extend to the non-emission area NEA. The first pixel electrode PE1 may pass through the gate-insulating layer 130, and may be connected to a first switching element T1. The second pixel electrode PE2 may pass through the gate-insulating layer 130, and may be connected to a second switching element T2. The third pixel electrode PE3 may pass through the gate-insulating layer 130, and may be connected to a third switching element T3.

Each of the first pixel electrode PE1, the second pixel electrode PE2, and the third pixel electrode PE3 may be a reflective electrode. Each of the first pixel electrode PE1, the second pixel electrode PE2, and the third pixel electrode PE3 may be formed of titanium (Ti), copper (Cu), or an alloy of titanium (Ti) and/or copper (Cu). Furthermore, each of the first, second, and third pixel electrodes PE1, PE2, and PE3 may have a stacked layer structure including titanium (Ti) and copper (Cu). In addition, each of the first, second, and third pixel electrodes PE1, PE2, and PE3 may have a stacked layer structure formed by stacking a high work function material layer formed of material, such as titanium oxide (TiO₂), indium tin oxide (ITO), indium zinc oxide (IZO), zinc oxide ZnO), indium tin zinc oxide (ITZO), or magnesium oxide (MgO), and a reflective material layer formed of silver (Ag), magnesium (Mg), aluminum (Al), platinum (Pt), lead (Pb), gold (Au), nickel (Ni), neodymium (Nd), iridium (Ir), chromium (Cr), lithium (Li), calcium (Ca), titanium (Ti), copper (Cu), or a compound thereof. The high work function material layer may be positioned over the reflective material layer, and thus may be closer to the light-emitting element LE. Each of the first, second, and third pixel electrodes PE1, PE2, and PE3 may have a multilayer structure including ITO/Mg, ITO/MgF, ITO/Ag, or ITO/Ag/ITO, but is not limited thereto.

A bank BNL may be positioned on the first pixel electrode PE1, the second pixel electrode PE2, and the third pixel electrode PE3. The bank BNL may include an opening that exposes the first pixel electrode PE1, an opening that exposes the second pixel electrode PE2, and an opening that exposes the third pixel electrode PE3, and may define the first emission area EA1, the second emission area EA2, the third emission area EA3, and the non-emission area NEA. In other words, an area of the first pixel electrode PE1 that is not covered by the bank BNL and that is exposed may correspond to the first emission area EA1. An area of the second pixel electrode PE2 that is not covered by the bank BNL and that is exposed may correspond to the second emission area EA2. An area of the third pixel electrode PE3 that is not covered by the bank BNL and that is exposed may correspond to the third emission area EA3. The remaining area where the bank BNL is positioned may correspond to the non-emission area NEA.

The bank BNL may include organic insulating material, such as polyacrylate-based resin, epoxy resin, phenolic resin, polyamide-based resin, polyimide-based resin, unsaturated polyesters resin, polyphenylene ether-based resin, polyphenylene sulfide-based resin, or benzocyclobutene (BCB).

The bank BNL may overlap color filters CF1, CF2, and CF3 and a light-blocking component BK of the wavelength conversion component 200. For example, the bank BNL may completely overlap the light-blocking component BK. Furthermore, the bank BNL may include the first color filter CF1, the second color filter CF2, and the third color filter CF3.

A plurality of light-emitting elements LE may be located on the first pixel electrode PE1, the second pixel electrode PE2, and the third pixel electrode PE3.

As illustrated in FIGS. 7 and 8, the light-emitting elements LE may be located in each of the first emission area EA1, the second emission area EA2, and the third emission area EA3. Each light-emitting element LE may be a vertical light-emitting diode element extending longitudinally in the third direction DR3. In other words, a length of the light-emitting element LE in the third direction DR3 may be greater than a length thereof in the horizontal direction. The length in the horizontal direction refers to a length in the first direction DR1 or a length in the second direction DR2. For example, the length of the light-emitting element LE in the third direction DR3 may be within a range from about 1 μm to about 5 μm.

The light-emitting element LE may be a micro light-emitting diode element. The light-emitting element LE may include a connection electrode 125, a first semiconductor layer SEM1, an electron barrier layer EBL, an active layer MQW, a superlattice layer SLT, a second semiconductor layer SEM2, and a third semiconductor layer SEM3, in the thickness direction of the display substrate 100 (in the third direction DR3). The connection electrode 125, the first semiconductor layer SEM1, the electron barrier layer EBL, the active layer MQW, the superlattice layer SLT, the second semiconductor layer SEM2, and the third semiconductor layer SEM3 may be successively stacked in the third direction DR3.

The light-emitting element LE may have a cylindrical, disk-shaped or rod-shaped structure having a width greater than a height. However, the shape of the light-emitting element LE is not limited to the aforementioned example, and may have various shapes, for example, shapes, such as a rod, a wire, or a tube, a faceted cylinder, such as a regular hexahedron, a rectangular parallelepiped, or a hexagonal cylinder, or an elongated shape with a partially inclined outer surface.

The connection electrode 125 may be located over each of the plurality of pixel electrodes PE1, PE2, and PE3. Hereinafter, the light-emitting element LE that is located on the first pixel electrode PE1 may be described by way of example.

The connection electrode 125 may adhere to the first pixel electrode PE1, thus functioning to apply an emission signal to the light-emitting element LE. The connection electrode 125 may be an ohmic connection electrode. However, the present disclosure is not limited thereto, and the connection electrode 125 may be a Schottky connection electrode. The light-emitting element LE may include at least one connection electrode 125. Although FIGS. 7 and 8 illustrates that the light-emitting element LE includes one connection electrode 125, the present disclosure is not limited thereto. In some cases, the light-emitting element LE may include a larger number of connection electrodes 125, or may be omitted. The following description of the light-emitting element LE may be applied equally, even if the number of connecting electrodes 125 changes or if other structures are further included.

The connection electrode 125 may reduce resistance between the light-emitting element LE and the first pixel electrode PE1 and may enhance adhesion therebetween when the light-emitting element LE is electrically connected to the first pixel electrode PE1 in the display device 10. The connection electrode 125 may include conductive metal oxide. For example, the connection electrode 125 may be formed of indium tin oxide (ITO). The connection electrode 125 may be brought direct contact with and connected to the underlying first pixel electrode PE1, and thus may be made of the same material as the first pixel electrode PE1. Furthermore, the connection electrode 125 may optionally further include a reflective electrode made of metal, such as aluminum (Al) with a high reflectivity, or a diffusion prevention layer including nickel (Ni). Hence, the adhesion between the connection electrode 125 and the first pixel electrode PE1 may be enhanced, thus resulting in improved contact characteristics.

Referring to FIG. 8, the first pixel electrode PE1 may include a lower electrode layer P1, a reflective layer P2, and an upper electrode layer P3. The lower electrode layer P1 may be located in the lowermost portion of the first pixel electrode PE1, and thus may be electrically connected with the corresponding switching element. The lower electrode layer P1 may include metal oxide, for example, titanium oxide (TiO₂), indium tin oxide (ITO), indium zinc oxide (IZO), zinc oxide (ZnO), indium tin zinc oxide (ITZO), or magnesium oxide (MgO).

The reflective layer P2 may be located on the lower electrode layer P1, thus reflecting light emitted from the light-emitting element LE upward. The reflective layer P2 may include metal with a high reflectivity, for example, silver (Ag), magnesium (Mg), aluminum (Al), platinum (Pt), lead (Pb), gold (Au), nickel (Ni), neodymium (Nd), iridium (Ir), chromium (Cr), lithium (Li), calcium (Ca), or an alloy thereof.

The upper electrode layer P3 may be located on the reflective layer P2, thus directly contacting the light-emitting element LE. The upper electrode layer P3 may be located between the reflective layer P2 and the connection electrode 125 of the light-emitting element LE, thus directly contacting the connection electrode 125. As described above, the connection electrode 125 may be formed of metal oxide. The upper electrode layer P3 may also be formed of metal oxide in the same manner as that of the connection electrode 125.

The upper electrode layer P3 may be formed of titanium (Ti), copper (Cu), or an alloy of titanium (Ti) and/or copper (Cu). Furthermore, the upper electrode layer P3 may have a stacked layer structure including titanium (Ti) and copper (Cu). The upper electrode layer P3 may include titanium oxide (TiO₂), indium tin oxide (ITO), indium zinc oxide (IZO), zinc oxide (ZnO), indium tin zinc oxide (ITZO), or magnesium oxide (MgO). In one or more embodiments, in the case where the connection electrode 125 is formed of ITO, the first pixel electrode PE1 may have a multilayer structure of ITO/Ag/ITO.

The first semiconductor layer SEM1 may be located on the connection electrode 125. The first semiconductor layer SEM1 may be a p-type semiconductor, and may include semiconductor material having a chemical formula of AlxGayIn1-x-yN (0≤x≤1, 0≤y≤1, 0≤x+y≤1). For example, the semiconductor material may include any one or more of p-type doped AlGaInN, GaN, AlGaN, InGaN, AlN, and/or InN. The first semiconductor layer SEM1 may be doped with a p-type dopant. The p-type dopant may be Mg, Zn, Ca, Se, Ba, or the like. For example, the first semiconductor layer SEM1 may include p-GaN doped with p-type Mg. A thickness of the first semiconductor layer SEM1 may have a range from about 30 nm to about 200 nm, but is not limited thereto.

The electron barrier layer EBL may be located on the first semiconductor layer SEM1. The electron barrier layer EBL may be a layer provided to mitigate or prevent an excessive amount of electrons from flowing into the active layer MQW. For example, the electron barrier layer EBL may include p-AlGaN doped with p-type Mg. A thickness of the electron barrier layer EBL may have a range from about 10 nm to about 50 nm, but is not limited thereto. Furthermore, the electron barrier layer EBL may be omitted.

The active layer MQW may be located on the electron barrier layer EBL. The active layer MQW may emit light by combination of electron-hole pairs in response to electric signals applied through the first semiconductor layer SEM1 and the second semiconductor layer SEM2.

The active layer MQW may include material having a single or multiple quantum well structure. In the case in which the active layer MQW includes material having a multiple quantum well structure, the active layer MQW may have a structure formed by alternately stacking a plurality of well layers and a plurality of barrier layers. Here, although the well layer may be formed of InGaN and the barrier layer may be formed of GaN or AlGaN, the present disclosure is not limited thereto. A thickness of the well layer may range from about 1 nm to about 4 nm. A thickness of the barrier layer may range from about 3 nm to about 10 nm.

Alternatively, the active layer MQW may have a structure formed by alternately stacking semiconductor materials having large band gap energy and semiconductor materials having small band gap energy, and may include III- to V-Group semiconductor materials depending on the wavelength band of light to be emitted. The light to be emitted from the active layer MQW is not limited to the first light, and may emit the second light (light in a green wavelength band) or the third light (light in a red wavelength band) depending on the case.

In detail, the color of light to be emitted from the active layer MQW may vary depending on the content of indium (In). For example, as the content of indium (In) decreases, the wavelength band of light emitted from the active layer may shift toward the red wavelength band. As the content of indium (In) increases, the wavelength band of light emitted from the active layer may shift toward the blue wavelength band. For example, if the content of indium (In) is about 15% or less, the active layer MQW may emit the first light in the red wavelength band with a main peak wavelength ranging from about 600 nm to about 750 nm. On the other hand, if the content of indium (In) is about 25%, the active layer MQW may emit the second light in the green wavelength band with a main peak wavelength ranging from about 480 nm to about 560 nm. Furthermore, if the content of indium (In) is about 35% or more, the active layer MQW may emit the third light in the blue wavelength band with a main peak wavelength ranging from about 370 nm to about 460 nm. With reference to FIG. 6, there will be described an example in which the active layer MQW emits light in the blue wavelength band with the main peak wavelength ranging from about 370 nm to about 460 nm.

The superlattice layer SLT may be located on the active layer MQW. The superlattice layer SLT may be a layer provided to mitigate stress between the second semiconductor layer SEM2 and the active layer MQW. For example, the superlattice layer SLT may be formed of InGaN or GaN. A thickness of the superlattice layer SLT may range from about 50 nm to about 200 nm. The superlattice layer SLT may be omitted.

The second semiconductor layer SEM2 may be located on the superlattice layer SLT. The second semiconductor layer SEM2 may be formed of an n-type semiconductor. The second semiconductor layer SEM2 may include semiconductor material having a chemical formula of AlxGayIn1-x-yN (0≤x≤1, 0≤y≤1, 0≤x+y≤ 1). For example, the second semiconductor layer SEM2 may include any one or more of n-type doped AlGaInN, GaN, AlGaN, InGaN, AlN, and/or InN. The second semiconductor layer SEM2 may be doped with an n-type dopant. The n-type dopant may be Si, Ge, Sn, or the like. For example, the second semiconductor layer SEM2 may be n-GaN doped with n-type Si. A thickness of the second semiconductor layer SEM2 may have a range from about 2 μm to about 4 μm, but is not limited thereto.

The third semiconductor layer SEM3 may be located on the second semiconductor layer SEM2. The third semiconductor layer SEM3 may be located between the second semiconductor layer SEM2 and the common electrode CE. The third semiconductor layer SEM3 may be formed of an undoped semiconductor. The third semiconductor layer SEM3 may be formed of material that includes the same material as the second semiconductor layer SEM2 and that is not doped with an n-type or p-type dopant. In one or more embodiments, the third semiconductor layer SEM3 may include at least one of undoped InAlGaN, GaN, AlGaN, InGaN, AlN, and/or InN, but is not limited thereto.

A planarization layer PLL may be located on the bank BNL and the pixel electrodes PE1, PE2, and PE3. The planarization layer PLL may planarize an underlying stepped portion to facilitate the formation of the common electrode CE as described below. The planarization layer PLL may be formed with a certain height to allow at least a portion of each of the plurality of light-emitting elements LE, e.g., an upper portion thereof, to protrude upward from an upper surface of the planarization layer PLL. In other words, with respect to an upper surface of the first pixel electrode PE1, the height of the planarization layer PLL may be less than that of the light-emitting element LE.

The planarization layer PLL may include organic material to planarize the underlying stepped portion. For example, the planarization layer PLL may include polyacrylate-based resin, epoxy resin, phenolic resin, polyamide-based resin, polyimide-based resin, unsaturated polyester-based resin, poly phenylenether-based resin, polyphenylenesulfide-based resin, benzocyclobutene (BCB), or the like.

The common electrode CE may be located on the planarization layer PLL and the plurality of light-emitting elements LE. In detail, the common electrode CE may be located on one surface of the first substrate 110 on which the light-emitting elements LE are formed, and may be positioned on the overall surfaces of the display area DA and the non-display area NDA. The common electrode CE may be located to overlap each of the emission areas EA1, EA2, and EA3 in the display area DA, and have a relatively small thickness to allow light emission.

The common electrode CE may be directly located on upper surfaces and side surfaces of the plurality of light-emitting elements LE. The common electrode CE may directly contact the second semiconductor layer SEM2 and the third semiconductor layer SEM3 on the side surface of the light-emitting element LE. As illustrated in FIG. 6, the common electrode CE may cover the plurality of light-emitting elements LE, and may be a common layer located to connect in common the plurality of light-emitting elements LE. The second semiconductor layer SEM2 having conductivity is patterned in each of the light-emitting elements LE, so that the common electrode CE can directly contact the side surface of the second semiconductor layer SEM2 of each light-emitting element LE, thus allowing a common voltage to be applied to each light-emitting element LE.

The common electrode CE is located on the overall surface of the first substrate 110 to allow a common voltage to be applied thereto. Hence, the common electrode CE may include low-resistance material. Furthermore, the common electrode CE may be formed with a relatively small thickness to facilitate transmission of light. For example, the common electrode CE may include low-resistance material, such as aluminum (Al), silver (Ag), copper (Cu), or the like. A thickness of the common electrode CE may range from about 10 Å to about 200 Å, but is not limited thereto.

Each of the light-emitting elements LE may be supplied with a pixel voltage or an anode voltage from the pixel electrode through the connection electrode 125, and may be supplied with a common voltage through the common electrode CE. The light-emitting element LE may emit light at a certain luminance in response to a voltage difference between the pixel voltage and the common voltage.

The plurality of light-emitting elements LE (e.g., inorganic light-emitting diodes) are located on the pixel electrodes PE1, PE2, and PE3, so that drawbacks associated with organic light-emitting diodes, such as vulnerability to moisture or oxygen, can be reduced or eliminated, thus leading to improved lifetime and reliability.

The first organic layer FOL may be placed on the bank BNL located in the non-emission area NEA.

The first organic layer FOL may be located to overlap the non-emission area NEA, and may not overlap the emission areas EA1, EA2, and EA3. The first organic layer FOL may be directly located on the bank BNL, and may be positioned to be spaced apart from the plurality of pixel electrodes PE1, PE2, and PE3 adjacent thereto. The first organic layer FOL may be positioned on the entirety of the first substrate 110, and may be located to enclose the plurality of light-emitting elements EA1, EA2, and EA3. The first organic layer FOL may be provided in an overall lattice shape.

The first organic layer FOL may function to detach the plurality of light-emitting elements LE that contacts an upper surface of the first organic layer FOL that corresponds to the non-emission area NEA. The first organic layer FOL, when laser light is irradiated thereon, may absorb energy and momentarily increase in temperature, thus resulting in ablation. Consequently, the plurality of light-emitting elements LE that contacts the upper surface of the first organic layer FOL may be detached from the upper surface of the first organic layer FOL.

The first organic layer FOL may include a polyimide-based compound. The polyimide-based compound of the first organic layer FOL may include a cyano group to absorb light with a wavelength of about 308 nm, for example, laser light. In one or more embodiments, each of the first organic layer FOL and the bank BNL may include a polyimide-based compound, or may include different polyimide-based compounds.

For example, the bank BNL may be made of a polyimide-based compound that does not include a cyano group, and the first organic layer FOL may be made of a polyimide-based compound that includes a cyano group. With regard to laser light with a wavelength of about 308 nm, the transmittance of the first organic layer FOL may be less than the transmittance of the bank BNL, where the transmittance of the bank BNL is about 60% or more, and the transmittance of the first organic layer FOL may be about 0%. The absorptance of the first organic layer FOL for the laser light with a wavelength of about 308 nm may be about 100%. The first organic layer FOL may have a thickness ranging from about 2 Å to about 10 μm. If the thickness of the first organic layer FOL is about 2 Å or more, the absorptance of laser light with a wavelength of about 308 nm may be enhanced. If the thickness of the first organic layer FOL is about 10 μm or less, a step difference between the first organic layer FOL and the pixel electrode PE1 may be reduced or prevented from increasing, whereby the light-emitting element LE can suitably adhere to the pixel electrode during a subsequent process.

The wavelength conversion component 200 may be located on the light-emitting component LEP. The wavelength conversion component 200 may include a partition wall PW, a wavelength conversion layer QDL, color filters CF1, CF2, and CF3, a light-blocking component BK, and a protective layer PTL.

The partition wall PW may be located on the common electrode CE in the display area DPA, and, along with the bank BNL, may partition the plurality of emission areas EA1, EA2, and EA3 from each other. The partition wall PW may be located to extend in the first direction DR1 and the second direction DR2, and may be formed in a lattice-like pattern in the entirety of the display area DA. Furthermore, the partition wall PW may not overlap the plurality of emission areas EA1, EA2, and EA3, and may overlap the non-emission area NEA.

The partition wall PW may include or define a plurality of openings OP1, OP2, and OP3, which expose the underlying common electrode CE. The plurality of openings OP1, OP2, and OP3 may include a first opening OP1 that overlaps the first emission area EA1, a second opening OP2 that overlaps the second emission area EA2, and a third opening OP3 that overlaps the third emission area EA3. Here, the plurality of openings OP1, OP2, and OP3 may correspond to the plurality of areas EA1, EA2, and EA3. In other words, the first opening OP1 may correspond to the first emission area EA1, the second opening OP2 may correspond to the second emission area EA2, and the third opening OP3 may correspond to the third emission area EA3.

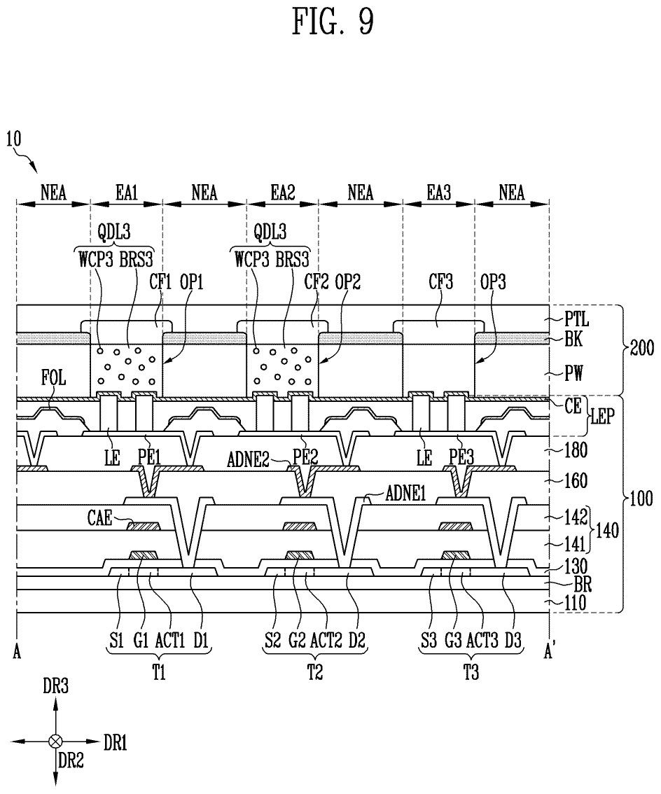

The partition wall PW may function to provide space for forming first and second wavelength conversion layers QDL1 and QDL2 (e.g., see FIG. 9). To achieve the aforementioned purpose, the partition wall PW may have a certain thickness. For example, the thickness of the partition wall PW may range from about 1 μm to about 10 μm. The partition wall PW may include organic insulating material to have a certain thickness. The organic insulating material may include, for example, epoxy-based resin, acrylic based resin, cardo-based resin, or imide-based resin.

The first wavelength conversion layer QDL1 may be located in each first opening OP1. The first wavelength conversion layer QDL1 may be formed in an island pattern having a shape in which dots are spaced apart from each other. The first wavelength conversion layer QDL1 may include a first base resin BRS1 and a first wavelength conversion particle WCP1. The first base resin BRS1 may include transparent organic material. For example, the first base resin BRS1 may include epoxy-based resin, acrylic-based resin, cardo-based resin, imide-based resin, or the like. The first wavelength conversion particle WCP1 may be a quantum dot (QD), a quantum rod, fluorescent material, or phosphorescent material. For example, a quantum dot may be particle material which emits light having a corresponding color while an electron makes a transition from the conduction band to the valence band.

The quantum dot may be semiconductor nanocrystal material. The quantum dot may have a corresponding bandgap depending on the composition and the size thereof, and thus may absorb light and then may emit light having an intrinsic wavelength. Examples of a semiconductor nanocrystal for the quantum dot may include a Group IV nanocrystal, a Group II-VI compound nanocrystal, a Group III-V compound nanocrystal, a Group IV-VI nanocrystal, and a combination thereof.

The first wavelength conversion layer QDL1 may be formed in the first opening OP1 in the first emission area EA1. The first wavelength conversion layer QDL1 may convert or shift the peak wavelength of incident light into a different corresponding peak wavelength of light, and then may emit the converted or shifted light. The first wavelength conversion layer QDL1 may convert a portion of blue light emitted from the light-emitting element LE into light similar to red light, which is the first light. The first wavelength conversion layer QDL1 emits light similar to red light, thus enabling the light to be converted into red right, which is the first light, through the first color filter CF1.

The second wavelength conversion layer QDL2 may be located in each second opening OP2 (e.g., see FIG. 9). The second wavelength conversion layer QDL2 may be formed in an island pattern having a shape in which dots are spaced apart from each other. For example, the second wavelength conversion layer QDL2 may be located to overlap the second emission area EA2. The second wavelength conversion layer QDL2 may include a second base resin BRS2 and a second wavelength conversion particle WCP2. The second base resin BRS2 may include transparent organic material. The second wavelength conversion layer QDL2 may convert or shift the peak wavelength of incident light into a different corresponding peak wavelength of light, and then may emit the converted or shifted light. The second wavelength conversion layer QDL2 may convert some of blue light emitted from the light-emitting element LE into light similar to green light, which is the second light. The second wavelength conversion layer QDL2 emits light similar to green light, thus enabling the light to be converted into green right, which is the second light, through the second color filter CF2.

In the third emission area EA3, only transparent organic material is formed in the third opening OP3, thus allowing blue light emitted from the light-emitting element LE to be emitted directly through the third color filter CF3 (e.g., see FIG. 9).

The plurality of color filters CF1, CF2, and CF3 may be located on the partition wall PW, and the first and second wavelength conversion layers QDL1 and QDL2. The plurality of color filters CF1, CF2, and CF3 may be located to overlap the plurality of openings OP1, OP2, and OP3 and the first and second wavelength conversion layers QDL1 and QDL2. The plurality of color filters CF1, CF2, and CF3 may include a first color filter CF1, a second color filter CF2, and a third color filter CF3.

The first color filter CF1 may be located to overlap the first emission area EA1. Furthermore, the first color filter CF1 may be located over the first opening OP1 of the partition wall PW to overlap the first opening OP1. The first color filter CF1 allows the first light emitted from the light-emitting element LE to pass therethrough, and may absorb or block the second light and the third light. For example, the first color filter CF1 allows light in the blue wavelength band to pass therethrough, and may absorb or block light in other wavelength bands, such as green and red.

The second color filter CF2 may be located to overlap the second emission area EA2. Furthermore, the second color filter CF2 may be located over the second opening OP2 of the partition wall PW to overlap the second opening OP2. The second color filter CF2 allows the second light to pass therethrough, and may absorb or block the first light and the third light. For example, the second color filter CF2 allows light in the green wavelength band to pass therethrough, and may absorb or block light in other wavelength bands, such as blue and red.

The third color filter CF3 may be located to overlap the third emission area EA3. Furthermore, the third color filter CF3 may be located over the third opening OP3 of the partition wall PW to overlap the third opening OP3. The third color filter CF3 allows the third light to pass therethrough, and may absorb or block the first light and the second light. For example, the third color filter CF3 allows light in the red wavelength band to pass therethrough, and may absorb or block light in other wavelength bands, such as blue and green.

A planar surface area of each of the color filters CF1, CF2, and CF3 may be greater than a planar surface area of each of the emission areas EA1, EA2, and EA3. For example, the planar surface area of the first color filter CF1 may be greater than that of the first emission area EA1. The planar surface area of the second color filter CF2 may be greater than that of the second emission area EA2. The planar surface area of the third color filter CF3 may be greater than that of the third emission area EA3. However, the present disclosure is not limited to the aforementioned example, and the planar surface area of each of the color filters CF1, CF2, and CF3 may be equal to the planar surface area of each of the emission areas EA1, EA2, and EA3.

Referring to FIG. 6, the light-blocking component BK may be located on the partition wall PW. The light-blocking component BK may overlap the non-emission area NEA, thus blocking transmission of light. The light-blocking component BK may be located in an approximately lattice shape in a plan view, in a manner similar to that of the bank BNL or the partition wall PW. The light-blocking component BK may be located to overlap the bank BNL, the first organic layer FOL, and the partition wall PW, and may not overlap the emission areas EA1, EA2, and EA3.

In one or more embodiments, the light-blocking component BK may include organic light-blocking material, and may be formed through processes, such as coating and exposure of organic blocking material, or the like. The light-blocking component BK may contain light-blocking dyes or pigments, and may be a black matrix. At least a portion of the light-blocking component BK may overlap the color filters CF1, CF2, and CF3 adjacent thereto. The color filters CF1, CF2, and CF3 may be located on at least a portion of the light-blocking component BK.

The protective layer PTL may be located on the plurality of color filters CF1, CF2, and CF3, and the light-blocking component BK. The first protective layer PTL may be located on the uppermost of the display device 10, thus protecting the underlying color filters CF1, CF2, and CF3, and the light-blocking component BK. One surface of the protective layer PTL, for example, a lower surface, may contact an upper surface of each of the color filters CF1, CF2, and CF3, and the light-blocking component BK.

The protective layer PTL may include inorganic insulating material to protect the color filters CF1, CF2, and CF3 and the light-blocking component BK. For example, the first protective layer PTL may include materials, such as silicon oxide (SiOₓ), silicon nitride (SiNₓ), silicon oxynitride (SiOₓN_{y}), aluminum oxide (AlₓO_{y}), aluminum nitride (AlN), or the like, but is not limited to thereto. The first protective layer PTL may have a certain thickness, for example, ranging from about 0.01 μm to about 1 μm. However, the present disclosure is not limited thereto.

FIG. 9 is a sectional view schematically illustrating a cross-section taken along the line A-A′ of FIG. 2 in accordance with one or more embodiments.

Referring to FIG. 9, the third wavelength conversion layer QDL3 may be located in each of the first and second openings OP1 and OP2.

The third wavelength conversion layer QDL3 may convert or shift the peak wavelength of incident light into a different corresponding peak wavelength of light, and then may emit the converted or shifted light. The third wavelength conversion layer QDL3 may convert some of blue first light emitted from the light-emitting element LE into yellow fourth light. In the third wavelength conversion layer QDL3, the first light and the fourth light are mixed with each other to emit white fifth light. The fifth light may be converted into the first light through the first color filter CF1, and may be converted into the second light through the second color filter CF2.

The third wavelength conversion layer QDL3 may be located in each of the first and second openings OP1 and OP2, which are spaced apart from each other. In other words, the third wavelength conversion layer QDL3 may be formed in an island pattern having a shape in which dots are spaced apart from each other. For example, the third wavelength conversion layer QDL3 may be located only in each of the first opening OP1 and the second opening OP2, and may correspond thereto on a one-to-one basis. Furthermore, the third wavelength conversion layer QDL3 may be located to overlap each of the first emission area EA1 and the second emission area EA2. In one or more embodiments, the third wavelength conversion layer QDL3 may completely overlap each of the first emission area EA1 and the second emission area EA2.

The third wavelength conversion layer QDL3 may include a third base resin BRS3 and a third wavelength conversion particle WCP3. The third base resin BRS3 may include transparent organic material. For example, the third base resin BRS3 may include epoxy-based resin, acrylic-based resin, cardo-based resin, imide-based resin, or the like.

The third wavelength conversion particle WCP3 may convert the first light incident from the light-emitting element LE into the fourth light. For example, the third wavelength conversion particle WCP3 may convert light in the blue wavelength band into light in the yellow wavelength band. The third wavelength conversion particle WCP3 may be a quantum dot (QD), a quantum rod, fluorescent material, or phosphorescent material. For example, a quantum dot may be particle material which emits light having a corresponding color while an electron makes a transition from the conduction band to the valence band.

As the third wavelength conversion layer QDL3 increases in thickness in the third direction DR3, the content of third wavelength conversion particles WCP3 included in the wavelength conversion layer QDL may increase, whereby light conversion efficiency of the third wavelength conversion layer QDL3 can be enhanced. Therefore, for example, the thickness of the third wavelength conversion layer QDL3 may be set considering the light conversion efficiency of the third wavelength conversion layer QDL3.

In the third wavelength conversion layer QDL3, some of the first light emitted from the light-emitting element LE may be converted into the fourth light. The third wavelength conversion layer QDL3 may mix the first light and the fourth light with each other to emit white fifth light. The fifth light emitted from the third wavelength conversion layer QDL3 may pass through the first color filter CF1 to transmit only the first light and pass through the second color filter CF2 to transmit only the second light, as described below. Hence, light emitted from the wavelength conversion component 200 may be red light and green light, which are the first light and the second light. In the third emission area EA3, only transparent organic material is formed in the third opening OP3, thus allowing blue light emitted from the light-emitting element LE to be emitted directly through the third color filter CF3. In this way, full-color may be implemented.

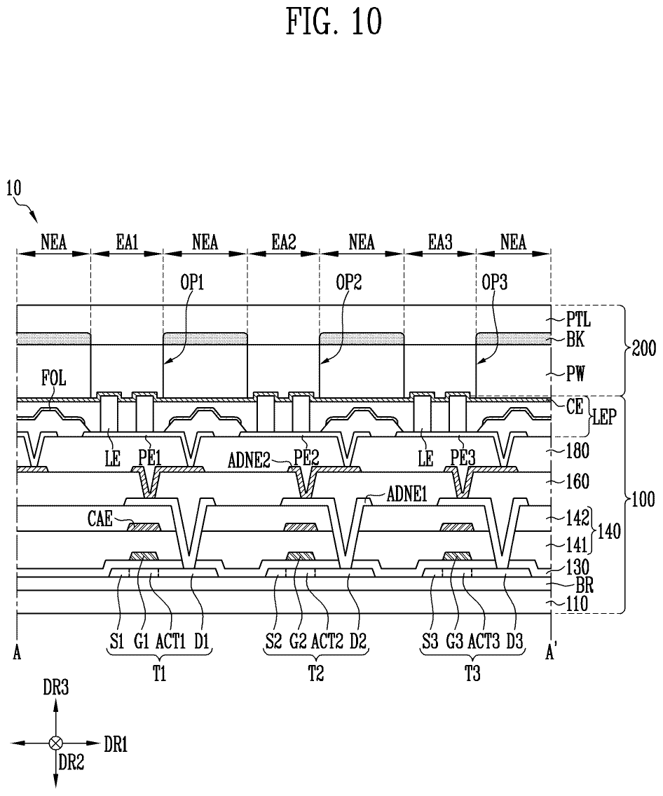

FIG. 10 is a sectional view schematically illustrating a cross-section taken along the line A-A′ of FIG. 2 in accordance with one or more embodiments.

As described above, the color of light emitted from the active layer MQW of each light-emitting element LE may vary depending on the content of indium (In). As the content of indium (In) decreases, the wavelength band of light emitted from the active layer may shift toward the red wavelength band. As the content of indium (In) increases, the wavelength band of light emitted from the active layer may shift toward the blue wavelength band. Therefore, in each light-emitting element LE formed in the first emission area EA1, the active layer MQW with an indium (In) content of about 15% or less may emit first light in the red wavelength band with a main peak wavelength ranging from about 600 nm to about 750 nm.

In each light-emitting element LE formed in the second emission area EA2, the active layer MQW with an indium (In) content of about 25% may emit second light in the green wavelength band with a main peak wavelength ranging from about 480 nm to about 560 nm.

In each light-emitting element LE formed in the third emission area EA3, the active layer MQW with an indium (In) content of about 35% or more may emit third light in the blue wavelength band with a main peak wavelength ranging from about 370 nm to about 460 nm.

Each light-emitting element LE formed in the first emission area EA1 may emit the first light in the red wavelength band. Each light-emitting element LE formed in the second emission area EA2 may emit the second light in the green wavelength band. Each light-emitting element LE formed in the third emission area EA3 may emit the third light in the blue wavelength band. In this case, there is no need to form the color filters CF1, CF2, and CF3.

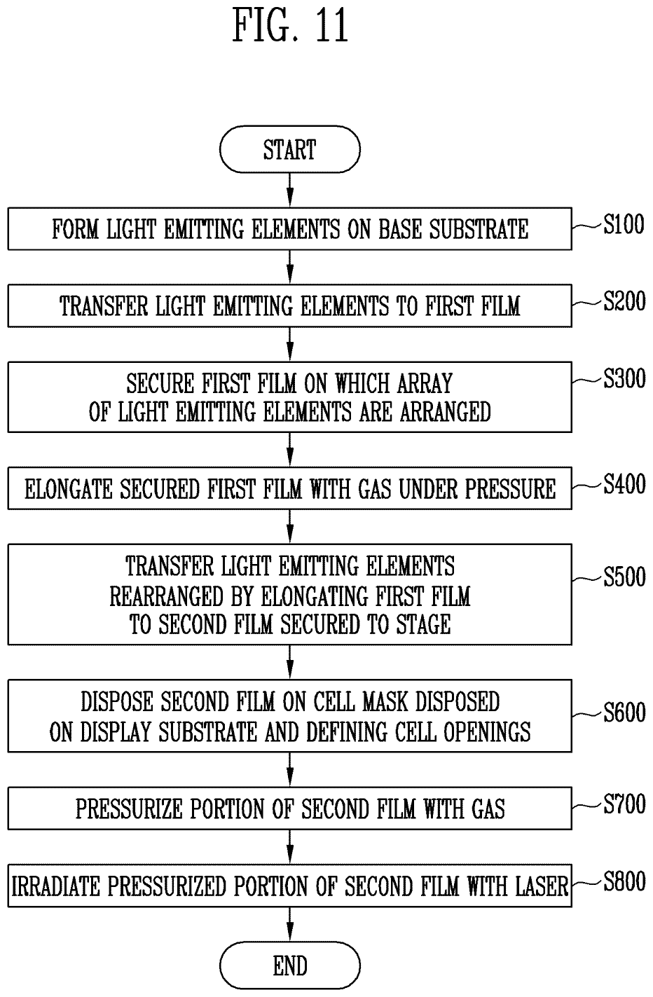

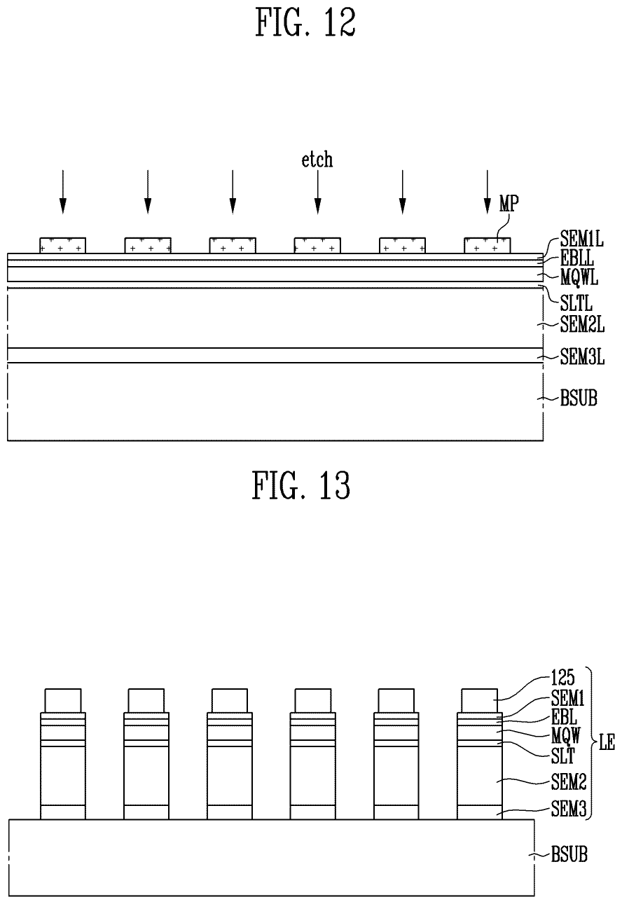

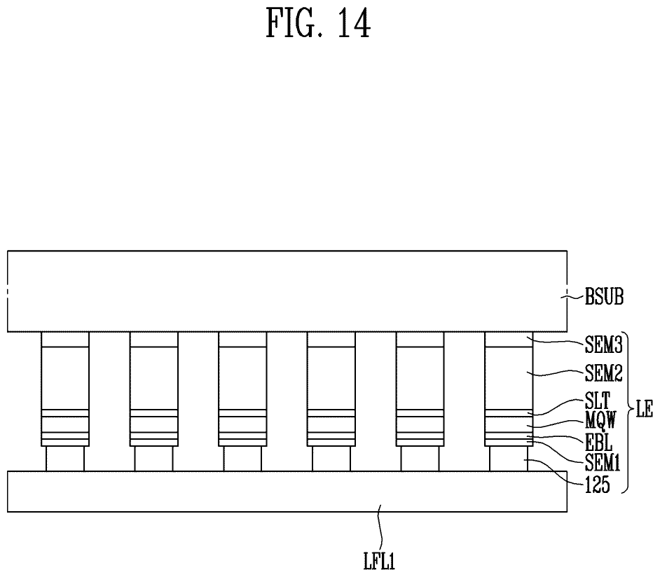

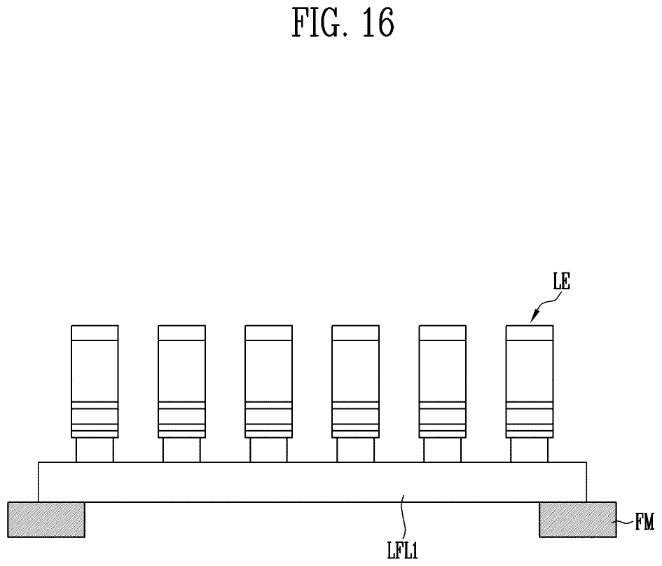

FIG. 11 is a flowchart for describing a method of fabricating the display panel in accordance with one or more embodiments. FIGS. 12 to 30 are diagrams schematically illustrating a process of fabricating the display panel in accordance with one or more embodiments.

Referring to FIGS. 11 to 13, the light-emitting elements LE may be formed on a base substrate BSUB (at operation S100). First, a sapphire substrate (Al₂O₃), a silicon wafer including silicon, or the like is prepared as the base substrate BSUB. A plurality of semiconductor material layers SEM3L, SEM2L, SLTL, MQWL, EBLL, and SEM1L are formed on the base substrate BSUB. The plurality of semiconductor material layers, which are grown by an epitaxial method may be formed by growing a seed crystal. In one or more embodiments, the method of forming the semiconductor material layers may include an electron beam deposition method, a physical vapor deposition (PVD) method, a chemical vapor deposition (CVD) method, a plasma laser deposition (PLD) method, a dual-type thermal evaporation method, a sputtering method, a metal organic chemical vapor deposition (MOCVD) method, or the like. It is desirable that the semiconductor material layers be formed by the MOCVD method. However, the present disclosure is not limited thereto.

Precursor material for forming the semiconductor material layers is not specifically limited so long as it can typically be selected within a range to form the target materials. For example, the precursor material may be metal precursors that include alkyl groups, such as methyl or ethyl groups. For example, the precursor material may include compounds, such as trimethyl gallium (Ga(CH₃)₃), trimethyl aluminum (Al(CH₃)₃), and triethyl phosphate ((C₂H₅)₃PO₄), but is not limited thereto.

In detail, a third semiconductor material layer SEM3L is formed on the base substrate BSUB. Although in the drawing there is an example in which one third semiconductor layer SEM3 is stacked, the present disclosure is not limited thereto, and a plurality of layers may be formed. The third semiconductor material layer SEM3L may be located to reduce a difference in lattice constant between a second semiconductor material layer SEM2L and the base substrate BSUB. For example, the third semiconductor material layer SEM3L may include an undoped semiconductor, and may be material that is not doped with an n-type or p-type dopant. In one or more embodiments, the third semiconductor material layer SEM3L may include at least one of undoped InAlGaN, GaN, AlGaN, InGaN, AlN, and/or InN, but is not limited thereto.

Using the above-mentioned method, the second semiconductor material layer SEM2L, a superlattice material layer SLTL, an active material layer MQWL, an electron barrier material layer EBLL, and a first semiconductor material layer SEM1L are successively formed on the third semiconductor material layer SEM3L. Thereafter, a plurality of light-emitting elements LE are formed by etching the semiconductor material layers SEM3L, SEM2L, SLTL, MQWL, EBLL, and SEM1L.

In detail, a plurality of mask patterns MP are formed on the first semiconductor material layer SEM1L. The mask patterns MP may include a hard mask including inorganic material, or a photoresist mask including organic material. The mask patterns MP may reduce or prevent the likelihood of the underlying semiconductor material layers SEM3L, SEM2L, SLTL, MQWL, EBLL, and/or SEM1L being etched. Subsequently, the semiconductor material layers are partially etched using the mask patterns MP as a mask, thus forming a plurality of light-emitting elements LE.

As illustrated in FIG. 13, on the base substrate BSUB, portions of the semiconductor material layers SEM3L, SEM2L, SLTL, MQWL, EBLL, and SEM1L that do not overlap the mask patterns MP are etched and removed, and the other portions that overlap the mask patterns MP and are not etched may be formed into the plurality of light-emitting elements LE.

The semiconductor material layers may be etched by a typical method. For example, a process of etching the semiconductor material layers may be a dry etching method, a wet etching method, a reactive ion etching (RIE) method, a deep reactive ion etching (DRIE) method, an inductively coupled plasma reactive ion etching (ICO-RIE) method, or the like. In the case of the dry etching method, anisotropic etching is possible, which makes it suitable for vertical etching. In the case where the etching method is used, Cl₂, O₂, or the like may be used as etchant. However, the present disclosure is not limited to the aforementioned example.

The portions of the semiconductor material layers SEM3L, SEM2L, SLTL, MQWL, EBLL, and SEM1L that overlap the mask patterns MP are not etched, and are thus formed into the plurality of light-emitting elements LE. Therefore, the plurality of light-emitting elements LE are formed including the third semiconductor layer SEM3, the second semiconductor layer SEM2, the superlattice layer SLT, the active layer MQW, the electron barrier layer EBL, and the first semiconductor layer SEM1.

Thereafter, a connection electrode material layer is stacked on the base substrate BSUB, and then is etched to form connection electrodes 125 on the plurality of light-emitting elements LE. The connection electrode 125 may be directly formed on the upper surface of the first semiconductor layer SEM1 of each light-emitting element LE. The connection electrode 125 may include transparent conductive material. For example, the connection electrode 125 may be formed of transparent conductive oxide (TCO), such as indium tin oxide (ITO) or indium zinc oxide (IZO). Furthermore, a highly reflective metal layer made of metal, such as aluminum (Au), copper (Cu), or gold (Au) may be additionally formed on the upper portion of the connection electrode 125 formed of transparent conductive oxide.

Referring to FIGS. 11, 14, and 15, the plurality of light-emitting elements LE may be transferred onto a first film LFL1 (at operation S200). The first film LFL1 is attached on the plurality of light-emitting elements LE formed on the base substrate BSUB. Therefore, the respective connection electrodes 125 of the plurality of light-emitting elements LE may be attached to the first film LFL1. A relatively large number of light-emitting elements LE are located, and thus can be attached to the first film LFL1 without being removed.

The first film LFL1 may include material capable of being elongated. The material capable of being elongated may include, for example, polyolefine, polyvinyl chloride (PVC), elastomeric silicone, elastomeric polyurethane, and/or elastomeric polyisoprene. The first film LFL1, including a support layer and an adhesive layer, may be used to adhere and support the plurality of light-emitting elements LE.

Thereafter, the base substrate BSUB is separated from the light-emitting elements LE by irradiating the base substrate BSUB with a laser. In other words, the base substrate BSUB may be separated from the respective third semiconductor layers SEM3 of the plurality of light-emitting elements LE.

Referring to FIGS. 11, 16, and 17, the first film LFL1 on which the plurality of light-emitting elements LE are arranged may be secured in place (at operation S300). The first film LFL1 on which the plurality of light-emitting elements LE are arranged may be secured in place by a fixing component FM. For example, the fixing component FM may include a fixing frame. The fixing frame may secure the first film LFL1 on which the plurality of light-emitting elements LE are arranged. An O-ring may be located between the fixing component FM and the first film LFL1 with an array of the light-emitting elements LE so as to reduce or prevent leakage of gas.

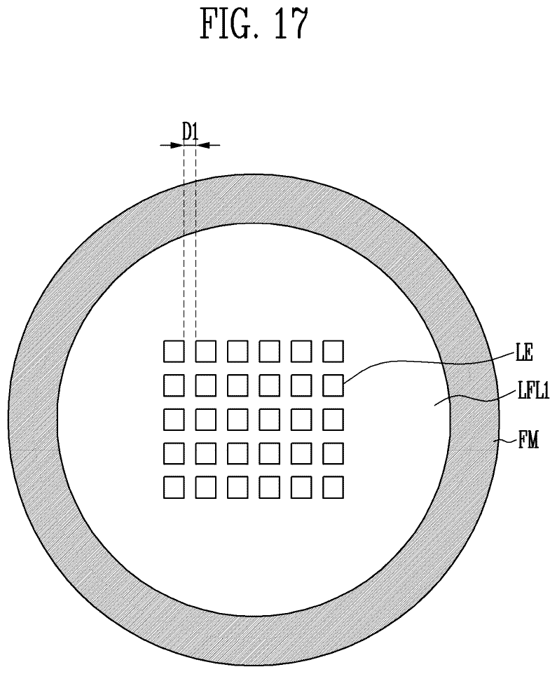

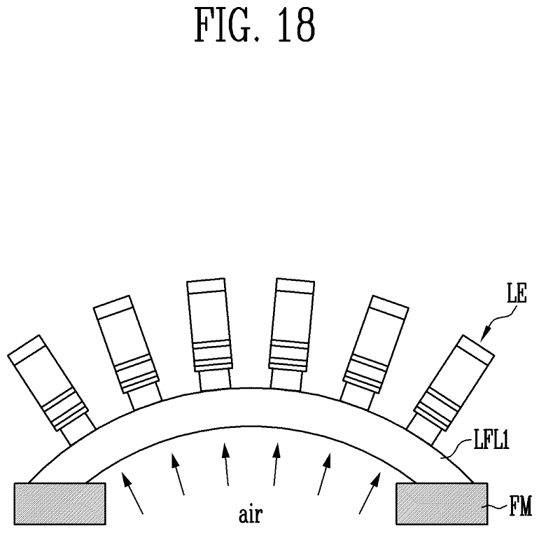

Referring to FIG. 17, on the first film LFL1 secured by the fixing component FM, the plurality of light-emitting elements LE are arranged with a first distance D1 therebetween.

Referring to FIGS. 11 and 18, the secured first film LFL1 may be elongated with gas under pressure (at operation S400). In one or more embodiments, the gas may be air, but is not limited thereto. The gas may be provided toward a rear surface of the first film LFL1, thus pressurizing the rear surface of the first film LFL1 in a front direction of the first film LFL1. Hence, the first film LFL1 may be elongated by the pressure of the gas. In one or more embodiments, the first film LFL1 may be elongated in a spherical shape. The pressure applied to the first film LFL1 by the gas may be substantially uniformly transmitted to the rear surface of the first film LFL1, whereby the first film LFL1 can be substantially uniformly elongated. In other words, the first film LFL1 may be isotropically elongated by the pressure of the gas. For example, the first film LFL1 is elongated by the pressure of the gas, thus reducing or preventing uneven elongation caused by friction with an elongation device that requires physical contact.

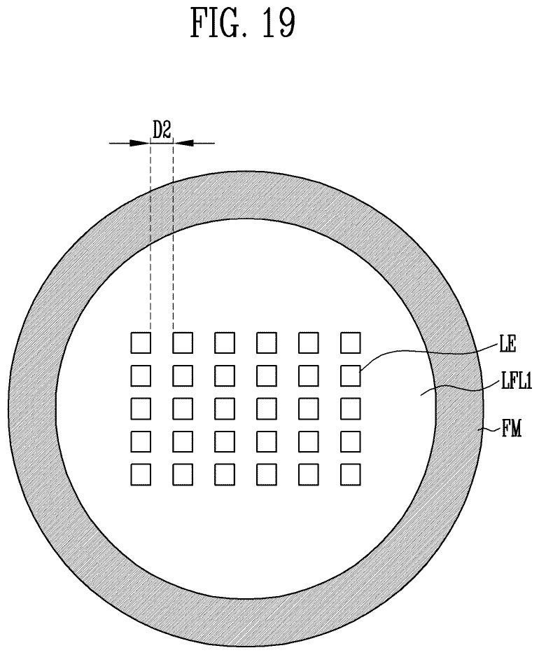

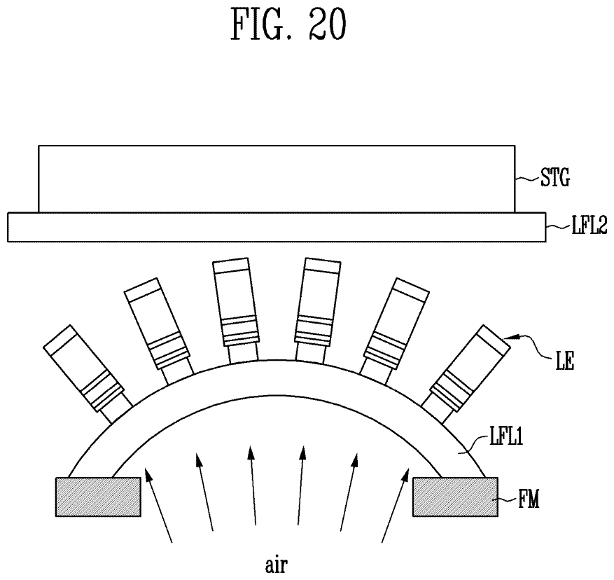

Referring to FIG. 19, on the elongated first film LFL1, the plurality of light-emitting elements LE are arranged at intervals of a second distance D2. In other words, as the first film LFL1 is elongated, the plurality of light-emitting elements LE may be substantially uniformly spaced apart from each other by the second distance D2 that is greater than the first distance D1.

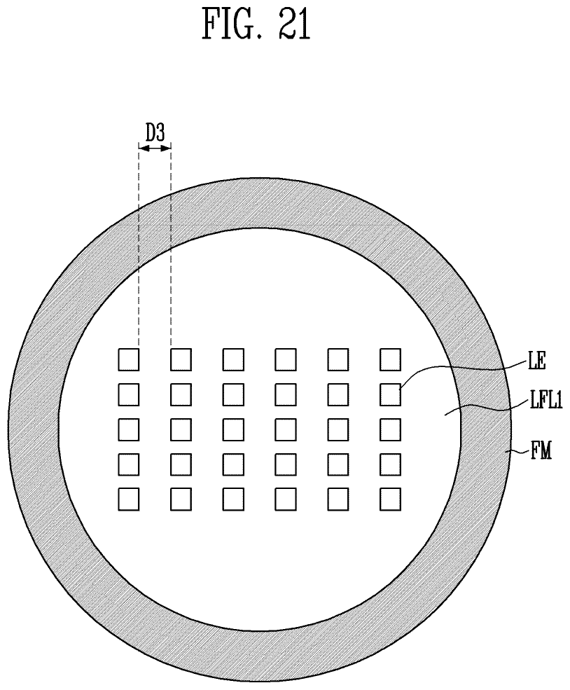

Referring to FIG. 20, in one or more embodiments, the first film LFL1 may be further elongated to a second film LFL2 spaced apart from the first film LFL1. Fixed to a stage STG, the second film LFL2 may be located over the first film LFL1 at a position spaced apart from the first film LFL1. In other words, maintaining a spherical shape, the first film LFL1 may be elongated to a position at which the plurality of light-emitting elements LE located on the first film LFL1 can be suitably transferred to the second film LFL2.

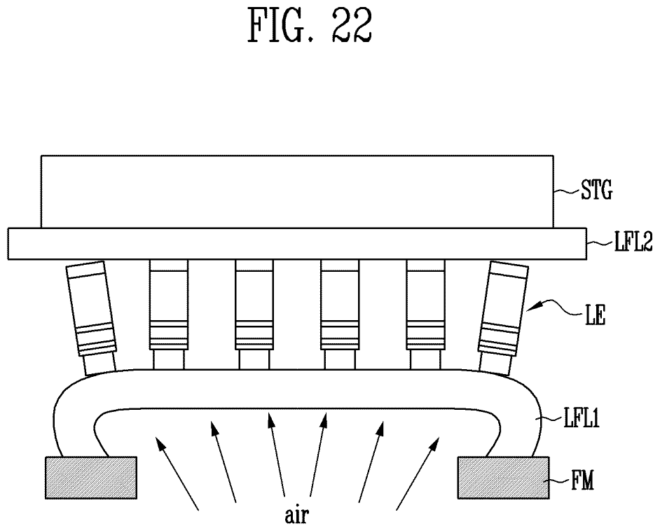

Referring to FIG. 21, on the elongated first film LFL1, the plurality of light-emitting elements LE are arranged at intervals of a third distance D3. In other words, as the first film LFL1 is further elongated, the plurality of light-emitting elements LE may be substantially uniformly spaced apart from each other by the third distance D3 greater than the second distance D2.

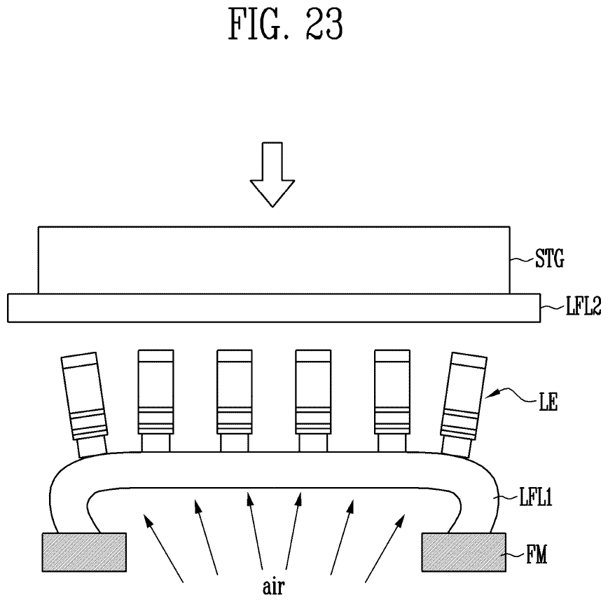

Referring to FIGS. 11 and 22, the plurality of light-emitting elements LE rearranged by the elongated first film LFL1 may be transferred to the second film LFL2 fixed to the stage STG. Here, a portion of the first film LFL1 elongated in a spherical shape may be pressurized by gas to make it flat in shape. For example, a portion of the first film LFL1 where the rearranged light-emitting elements LE are positioned may be pressurized with gas to become parallel to the second film LFL2. Therefore, the plurality of light-emitting elements LE can be suitably transferred to the second film LFL2.

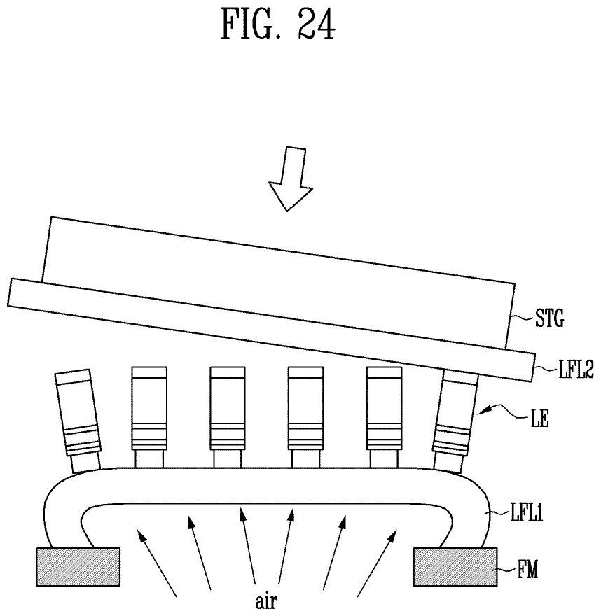

Referring to FIG. 23, at operation S500, the stage STG may move downward toward the elongated first film LFL1. Hence, the second film LFL2 fixed to the stage STG becomes close to the plurality of light-emitting elements LE, whereby the light-emitting elements LE can be suitably and substantially uniformly transferred to the second film LFL2. In other words, as the stage STG moves downward, excessive elongation of the first film LFL1 for transferring can be reduced or prevented, thus maintaining the distance between the plurality of light-emitting elements LE constant.

Referring to FIG. 24, at operation S500, the stage STG may move downward toward the elongated first film LFL1 while being inclined. Referring to FIG. 23, some of the plurality of light-emitting elements LE located on the first film LFL1 are not parallel to the second film LFL2, whereby transferring efficiency may be reduced. Given this, the stage STG moves downward while being inclined, so that the plurality of light-emitting elements LE located on the first film LFL1 may be efficiently transferred to the second film LFL2. For example, the stage STG moves downward while being inclined and rotates in one direction such that the plurality of light-emitting elements LE are successively transferred to the second film LFL2.

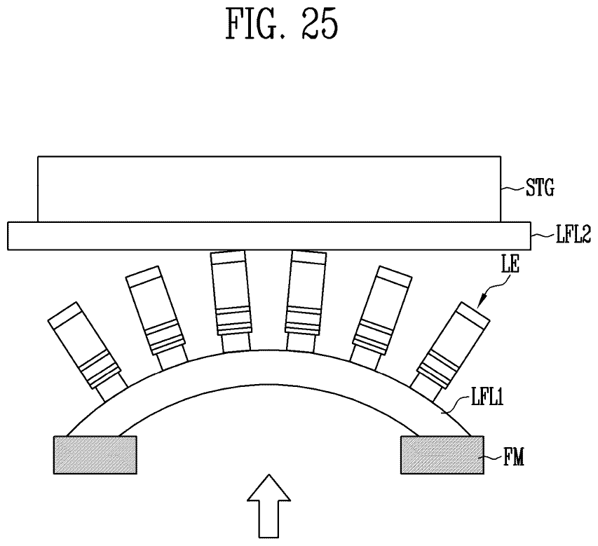

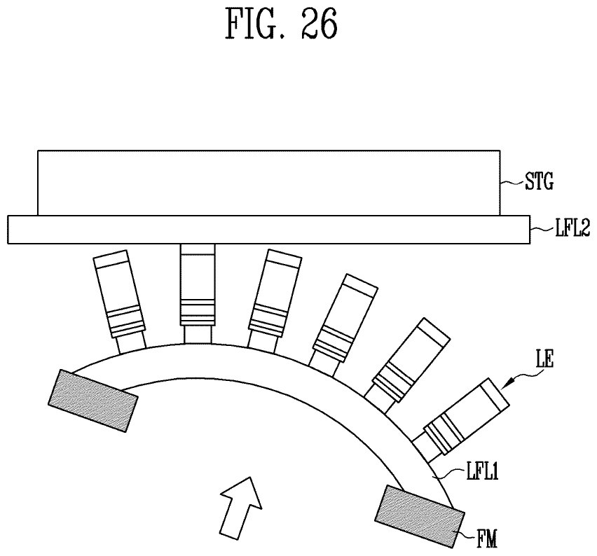

Referring to FIG. 25, the first film LFL1 elongated at operation S500 may move upward toward the second film LFL2. While the stage STG is stationary, the first film LFL1 moves upwardly to bring the second film LFL2 closer to the plurality of light-emitting elements LE, thus facilitating the transfer of the light-emitting elements LE to the second film LFL2. In other words, as the first film LFL1 moves upward, excessive elongation of the first film LFL1 for transferring can be reduced or prevented, thus maintaining the distance between the plurality of light-emitting elements LE constant.

Referring to FIG. 26, the first film LFL1 elongated at operation S500 may move upward toward the second film LFL2 while being inclined. Referring to FIG. 25, some of the plurality of light-emitting elements LE located on the first film LFL1 are not parallel to the second film LFL2, whereby transferring efficiency may be reduced. Given this, the first film LFL1 moves upward while being inclined, so that the plurality of light-emitting elements LE located on the first film LFL1 may be efficiently transferred to the second film LFL2. For example, the first film LFL1 moves upwardly while being inclined and rotates in one direction such that the plurality of light-emitting elements LE are successively transferred to the second film LFL2.

Referring to FIGS. 11, 27, and 28, the second film LFL2 may be located on a cell mask CMK that is located on the display substrate 100 and defines a plurality of cell openings COP.

The cell mask CMK may include a mask frame MF and the plurality of cell openings COP. The mask frame MF may define the appearance of the cell mask CMK. The mask frame MF may be formed of metallic material including at least one of iron (Fe) and/or nickel (Ni). For example, the mask frame MF may include an alloy of iron and nickel. However, the present disclosure is not limited to the aforementioned example, and the mask frame FR may include stainless steel (SUS) or an INVAR® alloy (INVAR is a registered trademark of Aperam Alloys IMPHY Joint Stock Company).

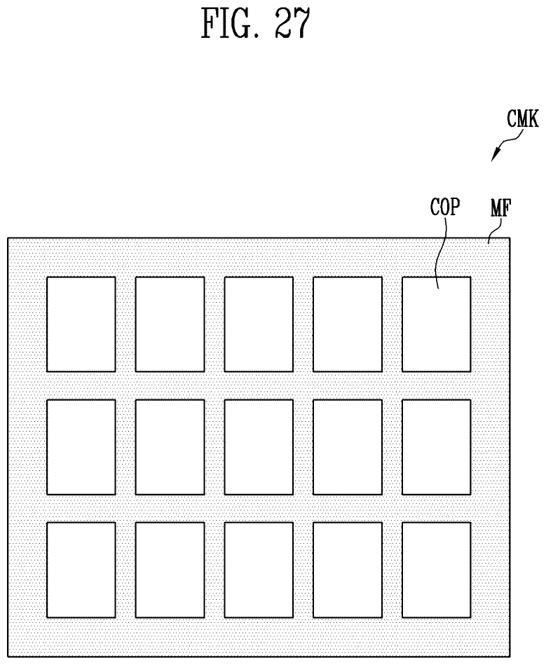

The plurality of cell openings COP passing through the mask frame MF may be defined in the mask frame MF. Each cell opening COP may correspond to one display panel. In other words, one cell opening COP may be used for a process of fabricating one display panel. Each of the cell openings COP may be formed in a shape corresponding to each of the display panels. For example, although in FIG. 27 there is illustrated an example in which each of the cell openings COP has a rectangular shape, the present disclosure is not limited thereto. Likewise, the number of cell openings COP is not limited to the embodiments corresponding to FIG. 27.

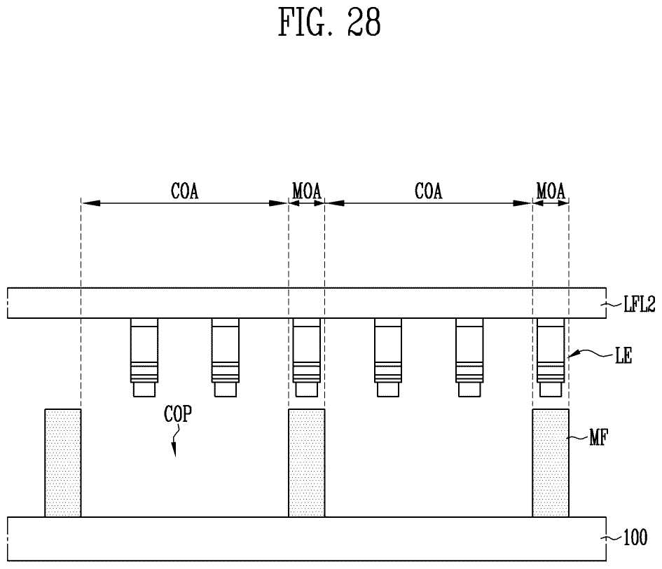

As shown in FIG. 28, the cell mask CMK may be located on/above the display substrate 100.

The second film LFL2 on which the plurality of light-emitting elements LE are arranged may be located over the cell mask CMK with a distance therebetween. In the second film LFL2, a plurality of first areas COA overlapping the plurality of cell openings COP and a plurality of second areas MOA overlapping the mask frame MF may be defined. Hence, the plurality of light-emitting elements LE located in the plurality of first areas COA overlapping the plurality of cell openings COP may face the display substrate 100 through the plurality of cell openings COP. On the other hand, at least one light-emitting element LE located in the plurality of second areas MOA overlapping the mask frame MF may face the mask frame MF, but may not face the display substrate 100. As such, the cell mask CMK may function to select light-emitting elements LE to be transferred to the display substrate 100 from among the plurality of light-emitting elements LE arranged on the second film LFL2 on a display panel basis.

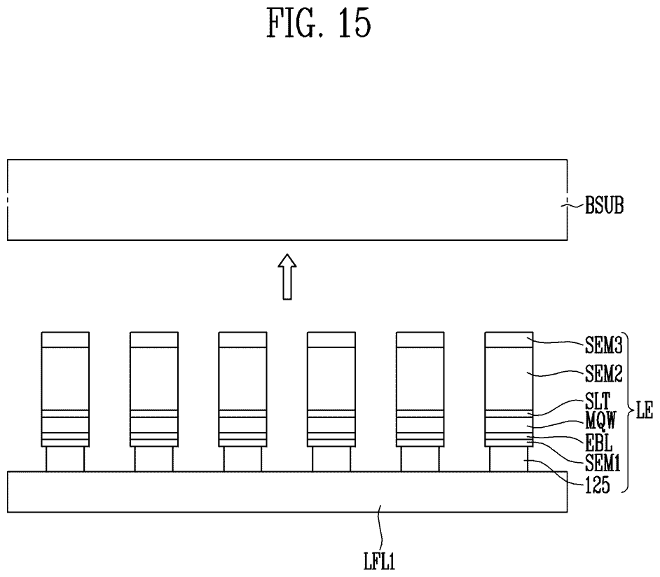

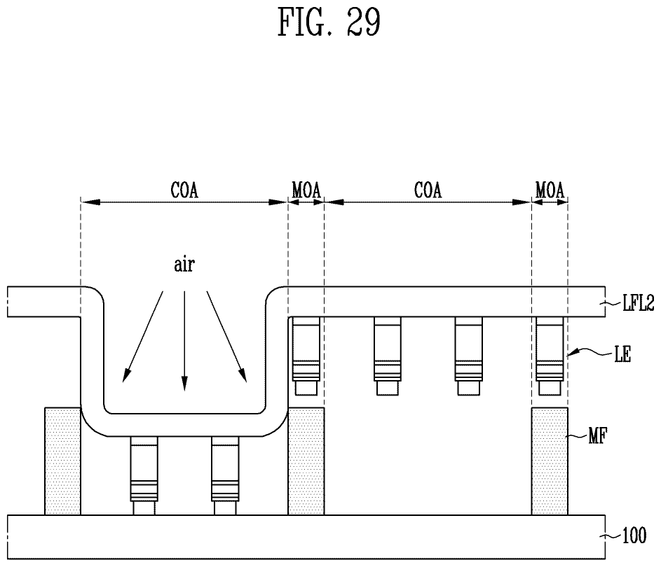

Referring to FIGS. 11 and 29, a portion of the second film LFL2 may be pressurized with gas. Here, the gas may be air, as described above, but is not limited thereto. In one or more embodiments, the portion of the second film LFL2 may be one of the plurality of first areas COA overlapping the plurality of cell openings COP (refer to FIG. 28). In other words, operation S700 may be performed on a cell opening (COP) basis. As one first area COA is pressurized with gas, the plurality of light-emitting elements LE that are located in the first area COA may contact the display substrate 100. For example, the respective connection electrodes 125 (refer to FIG. 15) of the plurality of light-emitting elements LE that are located in the one first area COA may contact the pixel electrode of the display substrate 100, for example, the first pixel electrode PE1 (refer to FIG. 8). For example, the pressure formed by gas is substantially uniformly transmitted to the plurality of light-emitting elements LE that are located in the first area COA. Hence, the light-emitting elements LE that are located in the first area COA may substantially uniformly contact the display substrate 100 without deviation.

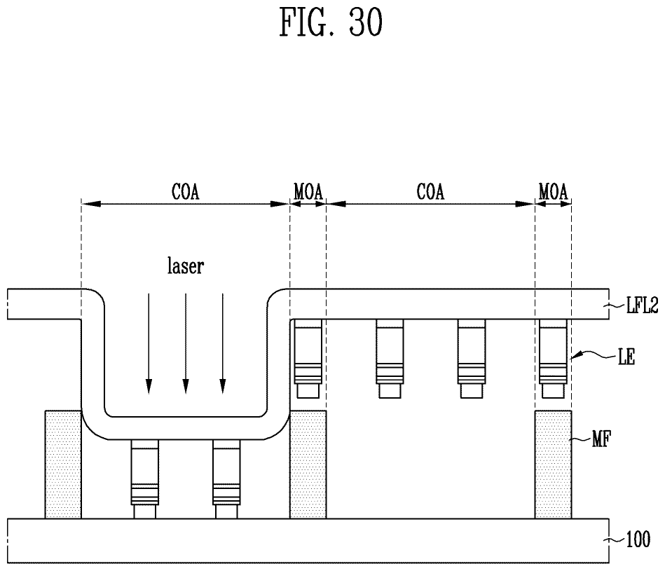

Referring to FIGS. 11 and 30, a laser may be irradiated onto the portion of the pressurized second film LFL2 (at operation S800). To transfer the plurality of light-emitting elements LE to the display substrate 100, heating should be performed along with the aforementioned pressurization at operation S700 such that the light-emitting elements LE can be completely bonded to the display substrate 100. The aforementioned bonding scheme may be referred to as eutectic bonding. Operation S800 may be performed on a cell opening (COP, refer to FIG. 28) basis. In other words, as a laser is irradiated onto a portion of the pressurized second film LFL2, the plurality of light-emitting elements LE that are located in the one first area COA may be bonded to the display substrate 100. For example, the respective connection electrodes 125 (refer to FIG. 15) of the plurality of light-emitting elements LE that are located in the one first area COA may be bonded to the pixel electrode of the display substrate 100, for example, the first pixel electrode PE1 (refer to FIG. 8).

Operation S700 and operation S800 may be repeatedly performed on a cell opening (COP) basis (e.g., a display panel basis), whereby display panels may be successively fabricated.

In accordance with embodiments of the present disclosure, a film is elongated using gas without physical friction, whereby distances between a plurality of light-emitting elements can substantially uniformly vary. Furthermore, the film is pressurized using gas, so that a plurality of light-emitting elements can be substantially uniformly arranged on a substrate of a display panel without deviation.

However, effects of the present disclosure are not limited to the above-described effects, and various modifications are possible without departing from the spirit and scope of the present disclosure.

The embodiments described in detail above are provided to explain the present disclosure, but it should be noted that the embodiments are not intended to limit the scope of the present disclosure. It should be understood by those skilled in the art that various changes, substitutions, and alternations may be made herein without departing from the scope of the disclosure as defined by the following claims with functional equivalents thereof to be included therein.

The scope of the present disclosure is not limited by detailed descriptions of the present specification, and should be defined by the accompanying claims. Furthermore, all changes or modifications of the present disclosure derived from the meanings and scope of the claims, and equivalents thereof should be construed as being included in the scope of the present disclosure.

What is claimed is:

1. A method of fabricating a display panel, the method comprising:
forming light-emitting elements on a base substrate;
initially transferring the light-emitting elements to a first film;
securing the first film on which the light-emitting elements are arranged;
elongating the first film by pressurizing the first film with gas; and
secondarily transferring the light-emitting elements, which are rearranged by elongating the first film, to a second film secured to a stage.

2. The method according to claim 1, wherein elongating the first film comprises elongating the first film in a spherical shape.

3. The method according to claim 1, wherein the gas comprises air.

4. The method according to claim 1, wherein a distance between the light-emitting elements increases due to elongating the first film.

5. The method according to claim 1, wherein elongating the first film comprises elongating the first film to the second film spaced apart from the first film.

6. The method according to claim 1, wherein secondarily transferring the light-emitting elements comprises pressurizing, with the gas, a portion of the first film on which the light-emitting elements are positioned, such that the portion is parallel to the second film.

7. The method according to claim 1, further comprising:
locating the second film on a cell mask that is above a display substrate and that defines cell openings;
pressurizing a portion of the second film with the gas; and
irradiating the portion of the second film with a laser.

8. The method according to claim 7, wherein the portion of the second film overlaps one of cell openings.

9. The method according to claim 8, wherein, in pressurizing the portion of the second film, the light-emitting elements rearranged and positioned in the portion of the second film contact the display substrate.

10. The method according to claim 7, wherein, in irradiating the portion, the light-emitting elements rearranged and positioned in the portion of the second film are bonded to the display substrate.

11. The method according to claim 7, wherein pressurizing the portion of the second film and irradiating the portion are performed on a basis of the cell openings.

12. The method according to claim 1, wherein, in secondarily transferring the light-emitting elements, the stage moves downwardly toward the first film.

13. The method according to claim 1, wherein, in secondarily transferring the light-emitting elements, the stage moves downwardly toward the first film while being inclined.

14. The method according to claim 1, wherein, in secondarily transferring the light-emitting elements, the first film moves upwardly toward the second film.

15. The method according to claim 1, wherein, in secondarily transferring the light-emitting elements, the first film moves upwardly toward the second film while being inclined.
